(19) United States
(12) Patent Application Publication
(10) Pub. No.: US 2026/0089967 A1
(43) Pub. Date: Mar. 26, 2026

(54) ANTIFERROELECTRIC MEMORY DEVICE

(71) Applicant: JAPAN SCIENCE AND TECHNOLOGY AGENCY, Saitama (JP)

(72) Inventors: Masaharu KOBAYASHI, Tokyo (JP); Zhuo LI, Tokyo (JP); Toshiro HIRAMOTO, Tokyo (JP)

(21) Appl. No.: 18/870,779

(22) PCT Filed: May 25, 2023
(86) PCT No.: PCT/JP2023/019580

§ 371 Date: Sep. 26, 2025

(30) Foreign Application Priority Data
Jun. 7, 2022 (JP) 2022-092490
Sep. 20, 2022 (JP) 2022-149329

(51) Int. Cl. H10B 51/30; H10D 30/69; H10D 64/68

(52) U.S. Cl. CPC H10B 51/30; H10D 30/701; H10D 64/689

(57) ABSTRACT

An antiferroelectric memory device includes a plurality of antiferroelectric memory elements. Each of the antiferroelectric memory elements comprises a semiconductor layer containing a metal oxide, a gate electrode facing the semiconductor layer; and a gate insulating layer comprised from an antiferroelectric material arranged between the semiconductor layer and the gate electrode. An electron affinity of a first material forming the gate electrode is smaller than an electron affinity of a second material comprising the semiconductor layer and the second material is an n-type semiconductor, or an electron affinity of the first material forming the gate electrode is greater than an electron affinity of the second material comprising the semiconductor layer and the second material is a p-type semiconductor.

### CROSS REFERENCE TO RELATED APPLICATIONS

This application is a Continuation of International Patent Application No. PCT/JP2023/019580, filed on May 25, 2023, which claims the benefit of priority to Japanese Patent Application No. 2022-092490, filed on Jun. 7, 2022 and Japanese Patent Application No. 2022-149329, filed on Sep. 20, 2022, the entire contents of which are incorporated herein by reference.

### FIELD

An embodiment of the present invention relates to a nonvolatile memory device. In particular, the present invention relates to an antiferroelectric memory device, which is a nonvolatile memory device including a plurality of antiferroelectric memory elements. Specifically, the present invention relates to an antiferroelectric memory device having a three-dimensional stacked structure in which a plurality of antiferroelectric memory elements are arranged in series.

### BACKGROUND

In recent years, with an increase in demand for a nonvolatile memory device, the development of a nonvolatile memory device using a ferroelectric material has been actively performed. In particular, an FeFET (Ferroelectric Field Effect Transistor) using a hafnium-oxide-based ferroelectric material as a gate insulating layer is attracting attention as a key device for realizing a high-density memory device integrated in a three-dimensional stacked structure because it consumes less power and can operate at a high speed as compared with a flash memory and is highly compatible with CMOS processes.

On the other hand, as a development of ferroelectric material progresses, attempts to use an antiferroelectric material in nonvolatile memory devices have also been increasing. A polarization characteristic curve (P-V curve) of the antiferroelectric material has a unique shape that resembles two hysteresis loops connected together and is also called a butterfly curve (see FIG. 1). In the following description, a hysteresis loop on the positive side of the vertical axis (a hysteresis loop indicated by a thick line in FIG. 1) of the butterfly curve may be abbreviated as a plus loop, and a hysteresis loop on the negative side of the vertical axis may be abbreviated as a minus loop. Due to such a unique shape of the polarization characteristic curve, the antiferroelectric material has a property that, although it is polarized and has hysteresis when an electric field is applied, the polarization becomes almost zero when the electric field is made zero. Therefore, even if the antiferroelectric material is simply used for a gate insulating layer, it does not operate as a nonvolatile memory device.

MILAN PESIC, TAIDE LI, VALERIO DI LECCE, MICHAEL HOFFMANN, MONICA MATERANO, CLAUDIA RICHTER, BENJAMIN MAX, STEFAN SLESAZECK, UWE SCHROEDER, LUCA LARCHER AND THOMAS MIKOLAJICK, “Built-In Bias Generation in Anti-Ferroelectric Stacks: Methods and Device Applications”, JOURNAL OF THE ELECTRON DEVICES SOCIETY, VOLUME 6, Page(s): 1019-1025, (2018) (hereinafter, referred to as “Non-Patent Literature 1”), Zhongxin Liang, Kechao Tang, Junchen Dong, Qijun Li, Yuejia Zhou, Runteng Zhu, Yanqing Wu, Dedong Han, and Ru Huang, “A Novel High-Endurance FeFET Memory Device Based on ZrO2 Anti Ferroelectric and IGZO Channel”, 2021 IEEE International Electron Devices Meeting (IEDM), Page(s): 17.3.1-17.3.4, (2021) (hereinafter, referred to as “Non-Patent Literature 2”), and Atanu K. Saha and Sumeet K. Gupta, “Modeling and Comparative Analysis of Hysteretic Ferroelectric and Anti-ferroelectric FETs”, 2018 76th Device Research Conference (DRC), (2018) (hereinafter, referred to as “Non-Patent Literature 3”) disclose a technique related to an AFeFET (AntiFerroelectric Field Effect Transistor) using the antiferroelectric material as a gate insulating layer. Specifically, Non-Patent Literatures 1 to 3 disclose a technique for causing an AFeFET to operate as a pseudo-non-volatile memory device using either the minus loop or the plus loop (hereinafter, also referred to as a “half hysteresis loop”). Non-Patent Literature 1 discloses a stacked structure in which the antiferroelectric material is arranged as a dielectric layer. Non-Patent Literature 2 discloses an AFeFET having an IGZO semiconductor channel using the antiferroelectric material as a gate insulating layer. Non-Patent Literature 3 discloses an AFeFET having a silicon semiconductor channel using the antiferroelectric material as a gate insulating layer. These techniques shift a flat-band voltage using a work-function difference between a semiconductor layer and a gate electrode, fixed charges present inside the gate insulating layer, or a dipole arranged at an interface of the gate insulating layer to allow for non-volatile memory operations that apparently use the half-hysteresis loop of the butterfly curve. Koji Kita and Akira Toriumi, “Origin of electric dipoles formed at high-k/SiO2 interface”, APPLIED PHYSICS LETTERS 94, Page(s): 132902-1-132902-3, (2009) (hereinafter referred to as “Non-Patent Literature 4”) describes an effect of a dipole arranged at an interface between various oxide layers and a silicon oxide layer on the flat-band voltage.

### SUMMARY

An antiferroelectric memory device according to an embodiment of the present invention includes a plurality of antiferroelectric memory elements. Each of the antiferroelectric memory elements comprises a semiconductor layer containing a metal oxide, a gate electrode facing the semiconductor layer, and a gate insulating layer comprised from an antiferroelectric material arranged between the semiconductor layer and the gate electrode. An electron affinity of a first material forming the gate electrode is smaller than an electron affinity of a second material comprising the semiconductor layer and the second material is an n-type semiconductor.

An antiferroelectric memory device according to an embodiment of the present invention includes a plurality of antiferroelectric memory elements. Each of the antiferroelectric memory elements comprises a semiconductor layer containing a metal oxide, a gate electrode facing the semiconductor layer. and a gate insulating layer comprised from an antiferroelectric material arranged between the semiconductor layer and the gate electrode. An electron affinity of the first material comprising the gate electrode is greater than an electron affinity of the second material forming the semiconductor layer and the second material is a p-type semiconductor.

An antiferroelectric memory device according to an embodiment of the present invention includes a plurality of antiferroelectric memory elements. Each of the antiferroelectric memory elements comprises a semiconductor layer containing a metal oxide, a gate electrode facing the semiconductor layer, a gate insulating layer comprised from an antiferroelectric material arranged between the semiconductor layer and the gate electrode and an interface layer between the gate insulating layer and the gate electrode. An electron affinity of a first material forming the gate electrode is smaller than an electron affinity of a second material forming the semiconductor layer and the second material is an n-type semiconductor, and the interface layer is comprised from silicon oxide or germanium oxide. Here, the thickness of the interface layer may be 0.5 nm or more and 5 nm or less.

In the above antiferroelectric memory device, when the second material forming the semiconductor layer is an n-type semiconductor, the gate insulating layer may have a fixed charge of −3 μC/cm² to 2 μC/cm². When indicating the numerical range, the description “A to B” shall mean “A or more and B or less”.

In the above antiferroelectric memory device, when the second material forming the semiconductor layer is an n-type semiconductor, the metal oxide may be an oxide of Sn or a composite oxide of In and Zn, and the electron affinity of the first material may be 4.9 eV or less.

In the above antiferroelectric memory device, when the second material forming the semiconductor layer is an n-type semiconductor, the first material may be n-type doped Si and/or Ge.

In the above antiferroelectric memory device, the first material may be a metallic material.

In the above antiferroelectric memory device, when the second material forming the semiconductor layer is an n-type semiconductor, the metal oxide may be an oxide of In or a composite oxide of In, Ga and Zn, and the electron affinity of the first material may be 4.3 eV or less.

In the above antiferroelectric memory device, the first material may be n-type doped Si and/or Ge.

In the above antiferroelectric memory device, the first material may be a metallic material.

An antiferroelectric memory device according to an embodiment of the present invention includes a plurality of antiferroelectric memory elements. Each of the antiferroelectric memory elements comprises a semiconductor layer containing a metal oxide, a gate electrode facing the semiconductor layer, and a gate insulating layer comprised from an antiferroelectric material arranged between the semiconductor layer and the gate electrode. The metal oxide is an oxide of Sn or a composite oxide of In and Zn, and an electron affinity of a first material forming the gate electrode is 4.9 eV or less.

An antiferroelectric memory device according to an embodiment of the present invention includes a plurality of antiferroelectric memory elements. Each of the antiferroelectric memory elements comprises a semiconductor layer containing a metal oxide, a gate electrode facing the semiconductor layer, and a gate insulating layer comprised from an antiferroelectric material arranged between the semiconductor layer and the gate electrode. The metal oxide is an oxide of In or a composite oxide of In, Ga and Zn, and an electron affinity of a first material forming the gate electrode is 4.3 eV or less.

In the above antiferroelectric memory device, the antiferroelectric material may be a composite oxide represented by HfₓZr₁₋ₓO₂ (0≤x≤0.4).

In the above antiferroelectric memory device, the thickness of the gate insulating layer may be 5 nm or more and 50 nm or less, preferably 8 nm or more and 30 nm or less, and most preferably 10 nm or more and 20 nm or less.

### DESCRIPTION OF THE DRAWINGS

FIG. 1 is a schematic graph for explaining a polarization characteristic curve of an antiferroelectric material.

FIG. 2A is a graph showing the measurement results of electrical characteristics of a capacitor manufactured using an antiferroelectric material.

FIG. 2B is a graph showing the measurement results of electrical characteristics of a capacitor manufactured using an antiferroelectric material.

FIG. 3A is a diagram showing a model for a simulation in an AFeFET according to an embodiment of the present invention.

FIG. 3B is a graph showing the simulation results of an Id-Vg characteristic in the AFeFET model shown in FIG. 3A.

FIG. 3C is a graph showing the simulation results of an operating point analysis in the AFeFET model shown in FIG. 3A.

FIG. 4A is a graph showing the simulation results of an operating point analysis in the AFeFET model shown in FIG. 3A.

FIG. 4B is a graph showing the dependence of an Id-Vg characteristic on a fixed charge in the AFeFET model shown in FIG. 3A.

FIG. 5A is a cross-sectional view showing a device structure of an antiferroelectric memory device according to an embodiment of the present invention.

FIG. 5B is a cross-sectional perspective view showing an element structure of an antiferroelectric memory device according to an embodiment of the present invention.

FIG. 6A is a cross-sectional view showing an element structure of an antiferroelectric memory device according to an embodiment of the present invention.

FIG. 6B is a cross-sectional TEM photograph in the vicinity of a trench of a prototype ferroelectric memory device.

FIG. 7 is a graph showing an Id-Vg characteristic measured using an antiferroelectric memory device according to an embodiment of the present invention.

FIG. 8A is a graph showing the results of measuring a rewrite endurance at room temperature of an antiferroelectric memory device according to an embodiment of the present invention.

FIG. 8B is a graph showing the results of measuring a retention characteristic of an antiferroelectric memory device at room temperature according to an embodiment of the present invention.

FIG. 9A is a graph showing the simulation results of an Id-Vg characteristic when a carrier density (N_{d}) of an oxide semiconductor layer is changed in an AFeFET model.

FIG. 9B is a graph showing the simulation results of an operating point analysis when a carrier density (N_{d}) of an oxide semiconductor layer is changed in an AFeFET model.

FIG. 10 is a graph showing the dependence of a memory window on a carrier density (N_{d}) of an oxide semiconductor layer in an AFeFET model.

FIG. 11A is a graph showing the simulation results of an Id-Vg characteristic when a thickness (t_{OS}) of an oxide semiconductor layer is changed in an AFeFET model.

FIG. 11B is a graph showing the simulation results of an operating point analysis when a thickness (t_{OS}) of an oxide semiconductor layer is changed in an AFeFET model.

FIG. 12 is a graph showing the dependence of a memory window on a thickness (t_{OS}) of an oxide semiconductor layer in an AFeFET model.

FIG. 13A is a graph showing the simulation results of an Id-Vg characteristic when a thickness (t_{AFe}) of an antiferroelectric layer is changed in an AFeFET model.

FIG. 13B is a graph showing the simulation results of an operating point analysis when a thickness (t_{AFe}) of an antiferroelectric layer is changed in an AFeFET model.

FIG. 14 is a graph showing the dependence of a memory window on a thickness (t_{AFe}) of an antiferroelectric layer in an AFeFET model.

FIG. 15A is a graph showing the simulation results of an Id-Vg characteristic when a composition of an antiferroelectric layer is changed in an AFeFET model.

FIG. 15B is a graph showing the simulation results of an operating point analysis when a composition of an antiferroelectric layer is changed in an AFeFET model.

FIG. 16A is a graph showing the simulation results of an Id-Vg characteristic when a fixed charge of an antiferroelectric layer is changed in an AFeFET model.

FIG. 16B is a graph showing the simulation results of an operating point analysis when a fixed charge of an antiferroelectric layer is changed in an AFeFET model.

### DESCRIPTION OF EMBODIMENTS

The present inventors have found that, in the process of studying an FeFET having an oxide semiconductor as a channel and using a ferroelectric material as a gate insulating layer, the FeFET using an oxide semiconductor as a channel has a disadvantage that an erase operation becomes insufficient. Generally, an oxide semiconductor used in an FET has n-type conductivity, so that the majority carriers are electrons. Therefore, the FeFET using the n-type oxide semiconductor as a channel can induce enough electrons in the channel to support the polarization of the gate insulating layer during a programming operation. However, in the FeFET using the n-type oxide semiconductor as a channel, a sufficient number of holes (minority carriers) cannot be induced in the channel to support the polarization of the gate insulating layer during the erase operation, resulting in an insufficient erase operation.

The above-described conventional techniques do not recognize the problems peculiar to the above-described oxide semiconductor, and do not solve the problem that, when the n-type oxide semiconductor is used as a channel of the antiferroelectric memory device, the erase operation of the AFeFET becomes as insufficient as the erase operation of the above-described FeFET.

The present invention has been made in consideration of the above problems, and an object is to realize a stable erase operation of the AFFET in an antiferroelectric memory device having a plurality of AFeFETs using the n-type oxide semiconductor as a channel.

Hereinafter, embodiments of the present invention will be described with reference to the drawings and the like. However, the present invention can be implemented in various aspects without departing from the gist thereof, and is not to be construed as being limited to the description of the embodiments exemplified below. In the drawings, the widths, thicknesses, shapes, and the like of the respective portions may be schematically represented in comparison with the actual embodiments for clarity of explanation, but the drawings are merely examples, and do not limit the interpretation of the present invention. In the present specification and the drawings, elements having the same functions as those described with respect to the above-described drawings are denoted by the same reference signs, and redundant descriptions thereof may be omitted.

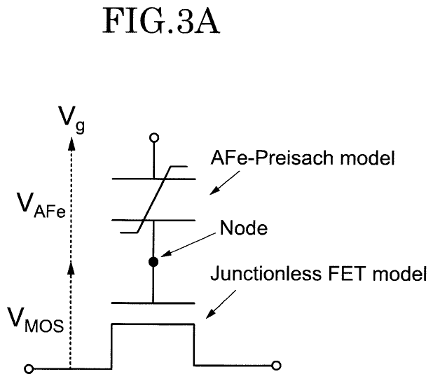

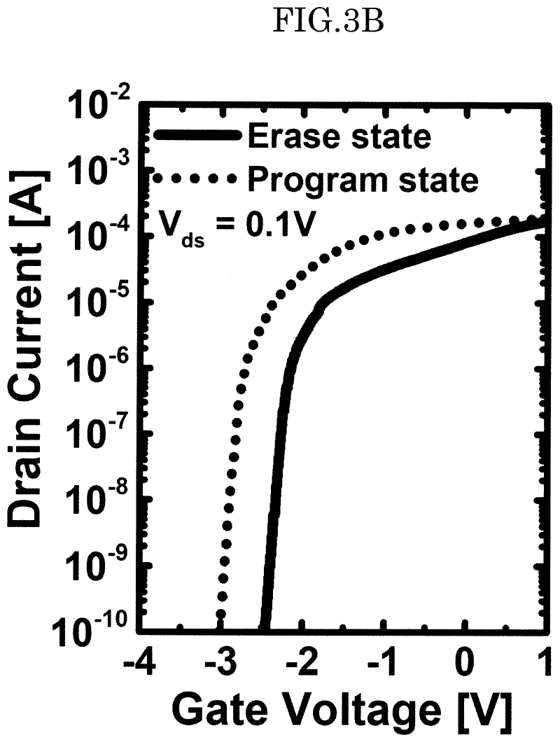

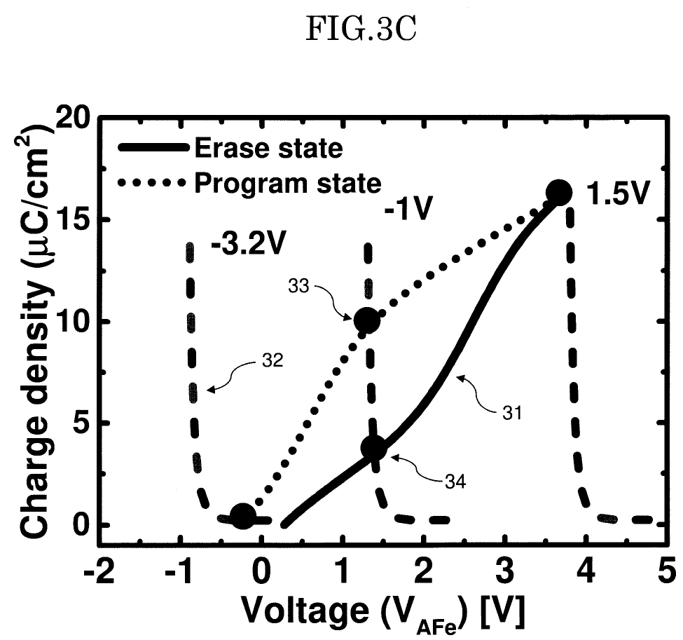

In the embodiments described below, the temperature conditions for the simulation are all room temperature.

[Basic Idea of Invention] In order to realize an antiferroelectric memory device having the n-type oxide semiconductor as a channel, the present inventors have studied an element structure based on the characteristics of the above-described n-type oxide semiconductor (characteristics that hardly induce minority carriers). As a result, the present inventors have conceived of a technical idea of using the plus loop of the polarization characteristic curve (butterfly curve) of the antiferroelectric material in a capacitor structure (stacked structure composed of gate electrode/gate insulating layer/semiconductor layer) using the antiferroelectric material as a material of the gate insulating layer. The technical idea is to use the plus loop by shifting a load curve of a FET (to be described later with reference to FIG. 3A and FIG. 3C) intersecting the polarization characteristic curve of the antiferroelectric material in the positive direction on the horizontal axis by applying a built-in voltage. In addition, in the antiferroelectric memory device having the p-type oxide semiconductor as a channel, the minus loop of the polarization characteristic curve of the antiferroelectric material may be used by shifting the load curve in the negative direction on the horizontal axis by applying the built-in voltage.

The conventional techniques describe the use of one of the hysteresis loops using a model in which the polarization characteristic curve of the antiferroelectric material is shifted by applying the built-in voltage. On the other hand, in the present invention describes the use of one of the hysteresis loops using a model in which the load curve of the FET is shifted by applying the built-in voltage. However, shifting the antiferroelectric polarization curve and shifting the load curve of the FET in the AFeFET represent the same phenomenon in different models. That is, shifting the polarization characteristic curve of the antiferroelectric material in the negative direction on the horizontal axis and shifting the load curve of the FET in the positive direction on the horizontal axis are equivalent as a model for using the plus loop of the polarization characteristic curve.

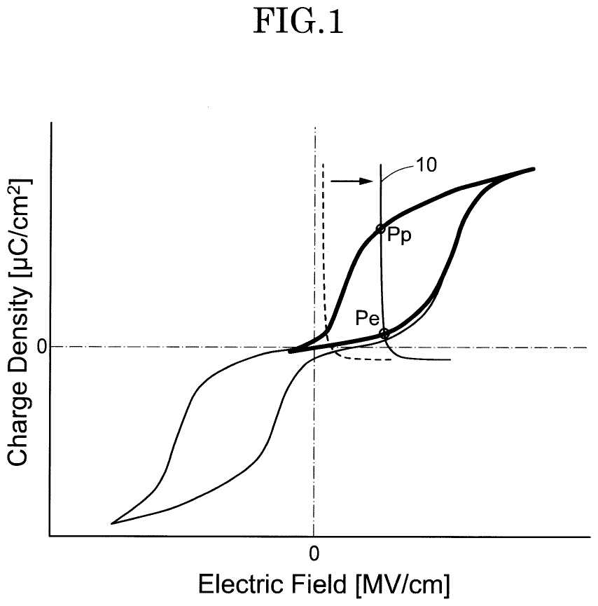

FIG. 1 is a schematic graph for explaining a polarization characteristic curve of an antiferroelectric material. In FIG. 1, the horizontal axis represents an electric field, and the vertical axis represents a polarization value (amount of charge per unit area). Generally, the polarization characteristic curve of the antiferroelectric material shows a butterfly-type hysteresis loop consisting of two half-hysteresis loops as shown in FIG. 1. In this case, even in a polarization state (program state) in which a large positive electric field is applied, or in a polarization state (erase state) in which a large negative electric field is applied, when the electric field becomes zero, almost the polarization disappears and there is no residual polarization. Therefore, in the case where the butterfly type hysteresis loop is used as it is, the antiferroelectric material cannot be used as a memory of the nonvolatile memory device. However, a method of using the half hysteresis loop as a memory has been proposed.

Specifically, there is a method in which an external bias voltage VB that maintains an electric field corresponding to the vicinity of the center of the half hysteresis loop is constantly applied to the gate of the nonvolatile memory device. In this case, a write operation (program or erase) can be performed by applying a voltage of V_{B}+V_{P} at the time of programming and V_{B}−V_{E} at the time of erasing, but the external bias voltage V_{B} needs to be contiguously applied even at the time other than the time of the write operation in order to retain the memory. On the other hand, in the Non-Patent Literature 1 described above, a method of using the half hysteresis loop by applying the built-in voltage instead of the external bias voltage is proposed.

The Non-Patent Literature 2 discloses an antiferroelectric FET having IGZO, which is the n-type oxide semiconductor, as a channel. Non-Patent Literature 2 discloses a configuration in which the external bias voltage is applied to the AFeFET and a configuration in which the minus loop is used by shifting the polarization characteristic curve (butterfly curve) of the antiferroelectric material in the positive direction on the horizontal axis. Non-Patent Literature 2 proposes a configuration in which the gate electrode is changed from TiN to Pt to apply the built-in voltage as a specific method of shifting the polarization characteristic curve in the positive direction.

However, in the case of using the minus loop, the antiferroelectric layer is in a non-polarized state during programming and a polarized state during erasing. In this case, it is preferrable that the semiconductor layer becomes a depletion state during programming and a state in which hole carriers are induced during erasing. The operation of the AFeFET when using the minus loop matches the characteristics of a silicon semiconductor, but not the characteristics of the n-type oxide semiconductor where almost no hole carriers are generated.

Therefore, the present inventors have conceived a configuration using the plus loop, contrary to conventional techniques. In the case of using the plus loop, the antiferroelectric layer is in a polarized state during programming and a non-polarized state during erasing. In this case, the semiconductor layer corresponds to a state induced by an electronic carrier during programming and a depletion state during erasing. Therefore, it is considered that the operation of the AFeFET when using the plus loop matches the characteristics of the n-type oxide semiconductor.

By applying the built-in voltage, the inventors shifted a load curve 10 (described below with reference to FIG. 3A and FIG. 3C) of the FET intersecting the polarization characteristic curve of the antiferroelectric material shown in FIG. 1 in the positive direction on the horizontal axis so that the antiferroelectric material remains polarized when the external voltage is zero. That is, as shown in FIG. 1, the present inventors set the vicinity of the center of the plus loop indicated by the thick line to be an operating point of the FET (the intersection of the polarization characteristic curve and the load curve 10). The present inventors have adopted a configuration in which the above-described operating point is used for reading the program state and the erase state, so that the antiferroelectric material is pseudo-used as a ferroelectric material. Since the plus loop has a shape similar to that of the hysteresis loop of the ferroelectric material, the AFeFET using the antiferroelectric material as the gate insulating layer can be operated in the same manner as the FeFET using the ferroelectric material as the gate insulating layer.

In FIG. 1, in the case where the polarization value in the retention state after the programming operation is Pp and the polarization value in the retention state after the erasing operation is Pe, the polarization value Pp indicates a positive value, and the polarization value Pe indicates a value close to approximately zero. In the case where the polarization Pp is positive, the n-type oxide semiconductor can induce enough electrons (majority carriers) to support the polarization. On the other hand, in the case where the polarization Pe is zero (or very small), the n-type oxide semiconductor can sufficiently support the polarization even if the induction of holes, which are minority carriers, is small. That is, even the n-type oxide semiconductor with the characteristics whereby it is difficult to induce holes, can realize an adequate erase operation.

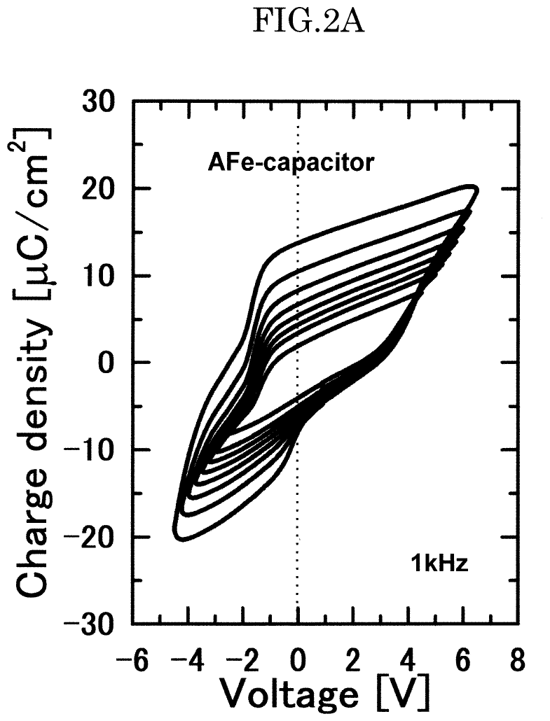

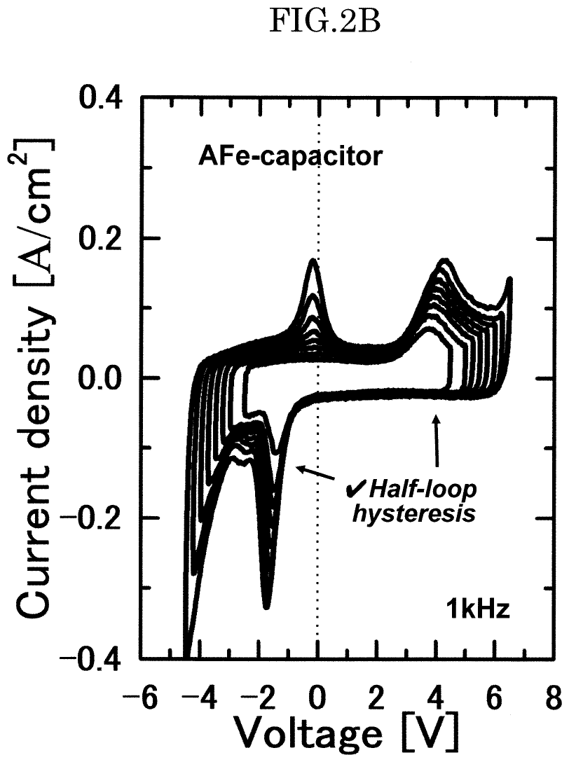

In this case, FIG. 2A and FIG. 2B are graphs showing the measurement results of electrical characteristics of a capacitor manufactured using the antiferroelectric material. Specifically, FIG. 2A shows P-V curves plotting the voltage on the horizontal axis and the polarization value (amount of charge per unit area) on the vertical axis. FIG. 2B shows I-V curves plotting the voltage on the horizontal axis and the current density on the vertical axis. The capacitor has an asymmetric structure in which zirconium oxide (zirconia) is sandwiched between the n-type silicon layer and a titanium nitride layer. With such a structure, the built-in voltage is applied to the capacitor, and the load curve 10 shown in FIG. 1 is shifted in the positive direction on the horizontal axis. Since an offset voltage of 1.5 V is applied to the voltage applied to the capacitor, a sweep range of the voltage is asymmetric. The voltage was an AC voltage of 1 kHz.

As shown in FIG. 2A and FIG. 2B, a double hysteresis loop (butterfly curve) changes to a single hysteresis loop as the sweep range of the voltage decreases. In particular, as shown in FIG. 2B, when the voltage is swept with the maximum sweep width, two current peaks are observed in the positive direction and the negative direction, whereas when the voltage is swept with the minimum sweep width, only one current peak is observed in the positive direction and the negative direction. That is, FIG. 2B shows that only one of the two half hysteresis loops exhibited by the antiferroelectric material can be used by narrowing the sweep range of the voltage. In FIG. 2B, the current peak in the negative direction near −4.5 V is caused by the leakage current, but the current peak is overlapped in the vicinity of −3.5 V. In addition, the current peak in the positive direction near 6.5 V is caused by the leakage current.

As described above, in the capacitor structure using the antiferroelectric material, the load curve of the AFeFET is shifted in the lateral direction by the asymmetric electrode structure, and the sweep range of the voltage applied between the electrodes is appropriately adjusted. As a result, in the capacitor structure of the present embodiment, it is possible to maintain the polarization of the program state and the erase state even when the voltage becomes zero by using only one of the two half hysteresis loops. Specifically, in the present embodiment, in the case where the n-type oxide semiconductor is used as a channel, the plus loop is used among the two half-hysteresis loops indicated by the antiferroelectric material due to the asymmetric electrode structure.

As described above, the present inventors have found that when the nonvolatile memory device using the n-type oxide semiconductor as a channel is manufactured, it is effective to use the antiferroelectric material as the gate insulating layer and selectively use the plus loop among the polarization characteristic curves of the antiferroelectric material. With such a configuration, it is possible to overcome the problem peculiar to the n-type oxide semiconductor that it is difficult to induce hole carriers, and to realize a highly reliable nonvolatile memory device that effectively utilizes the advantage of the n-type oxide semiconductor.

[Adjustment of Operating Point] When the plus loop is used among the two half-hysteresis loops of the antiferroelectric material based on the above-described basic idea, it is desirable to appropriately adjust the operating points of the individual memory elements (AFeFET). For example, as shown in FIG. 1, the load curve 10 (that is, the operating point) of the AFeFET is shifted so that the polarizations Pp and Pe can be maintained near the center of the plus loop. To shift the operating point, a method of applying the built-in voltage and shifting a flat-band voltage using a work-function difference between the gate electrode and the oxide semiconductor, fixed charges existing inside the gate insulating layer, and/or a dipole (hereinafter referred to as an “interface dipole”) arranged at an interface of the gate insulating layer can be applied. In this case, the operating point of the AFeFET will be described.

FIG. 3A is a diagram showing a model for a simulation in the AFeFET according to an embodiment of the present invention. As shown in FIG. 3A, the AFeFET of the present embodiment can be represented by a series connected antiferroelectric capacitor having the antiferroelectric material as a dielectric and a MOS transistor having an oxide semiconductor as a channel. In the FIG. 3A, the antiferroelectric capacitor is assumed to be a Preisach model, and the MOS transistor is assumed to be a junction-less FET model. In addition, it is assumed that there is a fixed charge at a node between the antiferroelectric capacitor and the MOS transistor. Vg is a source-gate voltage (hereinafter referred to as “gate voltage”) of the modeled AFeFET (hereinafter referred to as “AFeFET model”). The gate voltage is distributed to a first voltage (V_{AFe}) applied to a ferroelectric capacitor component and a second voltage (V_{MOS}) applied to the MOS transistor.

FIG. 3B is a graph showing the simulation results of an Id-Vg characteristic in the AFeFET model shown in FIG. 3A. The horizontal axis represents the gate voltage (V_{g}), and the vertical axis represents a drain current. A gate length (corresponding to a channel length) and a gate width were set to 50 μm, respectively. The source-drain voltage (Vds) was set to 0.1 V and the gate voltage was swept in a range from −5 V to 1 V. In addition, −2.5 V was set as the flat-band voltage (V_{FB}). As shown in FIG. 3B, the Id-Vg curve (dotted line) in the program state and the Id-Vg curve (solid line) in the erase state can be clearly distinguished from each other, and it can be confirmed that it operates as the AFeFET.

Next, FIG. 3C is a graph showing the simulation results of the operating point analysis in the AFeFET model shown in FIG. 3A. The horizontal axis represents the first voltage (V_{AFe}) applied to the antiferroelectric capacitor, and the vertical axis represents the polarization value (amount of charge per unit area). FIG. 3C shows a polarization characteristic curve 31 of the antiferroelectric capacitor and a load curve 32 of the MOS transistor superimposed on each other. The dotted line portion of the polarization characteristic curve 31 indicates the polarization characteristic of the program state, and the solid line portion indicates the polarization characteristic of the erase state.

The load curve 32 of the MOS transistor is a curve plotting the change in the dielectric charge amount (charge amount induced in the channel) of the MOS transistor to which the second voltage (V_{MOS}) corresponding to the difference between the gate voltage Vg and the first voltage (V_{AFe}) is applied when the first voltage (V_{AFe}) applied to the antiferroelectric capacitor is swept when a certain gate voltage Vg is applied. FIG. 3C shows the load curve 32 of the MOS transistor for each case where the gate voltage Vg applied to the gate of the AFeFET model is −3.2 V, −1 V, and 1.5 V.

As shown in FIG. 3C, when Vg is −1 V, the polarization characteristic curve 31 and the load curve 32 intersect at two points. The points where the polarization characteristic curve 31 and the load curve 32 intersect are referred to as operating points. An upper operating point 33 is an operating point when the AFeFET is in the program state, and a lower operating point 34 is an operating point when the AFeFET is in the erase state. The greater the distance between the upper operating point 33 and the lower operating point 34, the easier it is to distinguish between the program state and the erase state of the AFeFET.

In FIG. 3C, the load curve 32 varies in the left-right direction in response to changes in the flat-band voltage (V_{FB}) of the AFeFET. For example, the load curve 32 varies depending on the work-function difference between a material constituting the gate electrode of the AFeFET and a material constituting the semiconductor layer. In addition, the load curve 32 also varies with the interface dipole due to the interface layer between the gate electrode and the gate insulating layer. That is, by adjusting the work function difference or the interface dipole, a position of the load curve 32 in the left-right direction can be changed, and the operating point can be shifted to an appropriate position. Hereinafter, a specific method for adjusting the operating point of the AFeFET will be described.

[Adjustment by Work Function Difference] As described above, the load curve 32 shown in FIG. 3C can be shifted in the positive direction or negative direction on the lateral axis by adjusting the flat-band voltage VFB of the AFeFET. In the present embodiment, since the plus loop is selectively used among the polarization characteristic curves of the antiferroelectric material, the load curve 32 is shifted to the positive side. As a measure for this purpose, the work function of the material constituting the gate electrode of the AFeFET is made smaller than the work function of the material constituting the semiconductor layer. In addition, the work function of the semiconductor layer varies with the position of the Fermi level, that is, the carrier density. The electron affinity may be an indicator because the work function of a metal matches the electron affinity, and the work function of the semiconductor layer is approximately equal to the electron affinity when the carrier density is high. In this case, it can be said that the electron affinity (that is, the work function) of the material constituting the gate electrode of the AFeFET is smaller than the electron affinity of the material constituting the semiconductor layer.

According to the findings of the present inventors, in order to shift the load curve 32 to a practical position in driving the AFeFET having the antiferroelectric material as the gate insulating layer, it is desirable to arrange a work function difference of 1 eV or more between the material constituting the gate electrode and the material constituting the semiconductor layer. In view of this, when the oxide semiconductor having a work function of about 4.4 eV, for example, IGZO, is used as the semiconductor layer, the minus loop can be used by selecting a known material having a work function of 5.4 eV or more, for example, Pt proposed in Non-Patent Literature 2, as the material of the gate electrode.

However, in order to use the plus loop as proposed in the present invention using only the work function differences, selecting a metal with a work function of 3.4 eV or less is required. Metal materials containing alkali metals or alkaline earth metals (such as Cs, Ca) or lanthanoids (such as La, Eu) are known as low-work-function metals. However, since these materials are highly active, there are many restrictions on their use as the material of the gate electrode when considering the actual manufacturing process.

Therefore, in reality, when the oxide semiconductor having a work function of 4.4 eV or less is used, it is desirable to be able to use the plus loop by combining the adjustment by the composition of the antiferroelectric material, which will be described later, the adjustment by the fixed charge or the like, or the adjustment by the interface dipole, and the adjustment by the work function difference (that is, the difference in the electron affinity) described above.

In the present embodiment, since the n-type semiconductor layer is used as the oxide semiconductor, a material having a smaller work function (that is, electron affinity) than the n-type oxide semiconductor used as the oxide semiconductor is used as the material of the gate electrode. Specifically, a conductive material having a work function of 0.1 eV or more (preferably, 0.4 eV or more) smaller than that of the n-type oxide semiconductor used as the semiconductor layer is used as the material of the gate electrode. A metal material or a semiconductor material doped with an impurity can be used as the conductive material. For example, in the case where indium oxide (InOₓ) having a work function of about 4.4 to 4.5 eV or a metal oxide containing In, Ga, and Zn (IGZO) is used as the material constituting the semiconductor layer, n-type doped silicon (n-type silicon) having a work function of about 4.0 eV or n-type doped germanium (n-type germanium) may be used as the material of the gate electrode. In addition, in the case where a material having a work function larger than that of indium oxide or IGZO, for example, tin oxide (SnOₓ) having a work function of about 4.8 eV or metal oxide containing In and Zn (IZO) having a work function of about 5.0 eV is used as the material constituting the semiconductor layer, titanium nitride (TiN) having a work function of about 4.4 eV or n-type silicon having a work function of about 4.0 eV may be used. In the case where TiN is used as the gate electrode, for example, it may be a stacked gate structure in which TiN is arranged at a portion in contact with the gate insulating layer, and a metal layer such as tungsten (W) arranged thereon. In addition, in the case where indium tin oxide (ITO) having a work function about 4.7 eV or aluminum-doped zinc oxide (ZnO:Al) having a work function about 4.6 eV is used as the constituent material of the semiconductor layer, the work function difference can be adjusted by combining with an appropriate gate electrode.

In addition, in the case where a p-type oxide semiconductor is used as the semiconductor layer, the minus loop may be used by using a material having a higher work function (that is, electron affinity) than the p-type oxide semiconductor as the material of the gate electrode. Examples of the p-type oxide semiconductor include NIO, Cu₂O, β-TeO₂, CuCO₂O₄, CuAlO₂, LaCuOSe, CuRhO₂, SnO, Ta₂SnO₆, Sn₂Nb₂O₇. For example, it is preferable to use RuOx or Pt having a work function of 5.3 to 5.4 eV as the gate electrode.

As described above, the load curve 32 shown in FIG. 3C can be shifted to the positive side (positive direction) by the work function difference (or the difference in the electron affinity) between the material constituting the gate electrode and the material constituting the semiconductor layer. However, if the work function difference cannot be increased due to the constraint of material selection, the operating point may not be shifted to an appropriate position by the work function difference alone. In such a case, it is also desirable to use the adjustment by the fixed charge and/or the interface dipole described below.

[Adjustment by Fixed Charge] A fixed charge is an immobile charge present inside or at an interface of the insulating layer. In the present embodiment, it is assumed that the fixed charge exists inside or at the interface of the gate insulating layer composed of the antiferroelectric material. As discussed below, in order to shift a flat region of the load curve 32 shown in FIG. 3C upward, it is desirable that a negative fixed charge exists inside or at the interface of the gate insulating layer. In the case where zirconium oxide (ZrO₂) is used as the antiferroelectric material as in the present embodiment, oxygen vacancies or the like in a film act as a positive fixed charge. As discussed below, since the positive fixed charge shifts the flat region of the load curve 32 shown in FIG. 3C downward, it is preferable that the amount of the positive fixed charge in the gate insulating layer is small. However, even if the positive fixed charge is present, the flat region of the load curve 32 can be shifted to the appropriate position by supplying the negative fixed charge that exceeds the positive fixed charge to the gate insulating layer. According to the findings of the present inventors, the gate insulating layer composed of the antiferroelectric material preferably has a fixed charge of −3 μC/cm² to 2 μC/cm², and more preferably has a fixed charge of −2 μC/cm² to −1 μC/cm².

The amount of negative fixed charges present in the gate insulating layer can be adjusted by adjusting the film quality of the gate insulating layer according to the deposition conditions, or by adding ion species intentionally acting as the negative fixed charge in the gate insulating layer after the deposition of the gate insulating layer. For example, the amount of negative fixed charges may be adjusted by adding ion species acting as the negative fixed charge by ion implantation or a plasma treatment after the deposition of the gate insulating layer.

In this case, in the AFeFET model shown in FIG. 3A, it is assumed that there is a fixed charge at the node between the antiferroelectric capacitor and the MOS transistor. The present inventors confirmed the influence of the increase or decrease in the fixed charge on the load curve 32 by simulation.

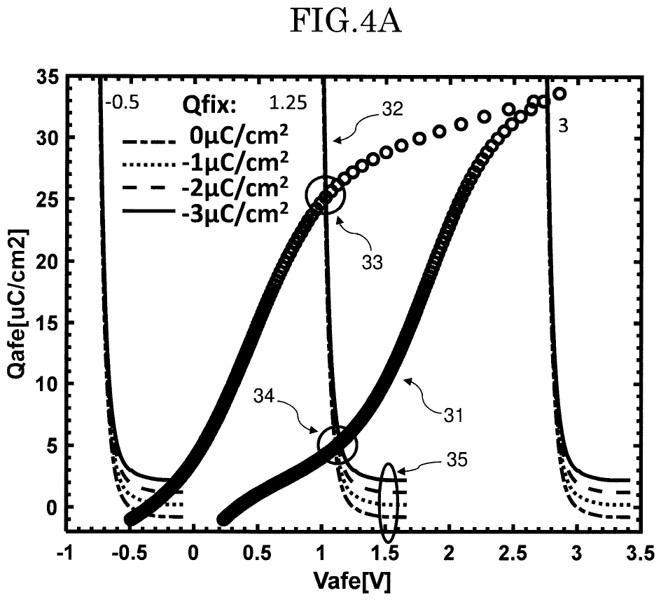

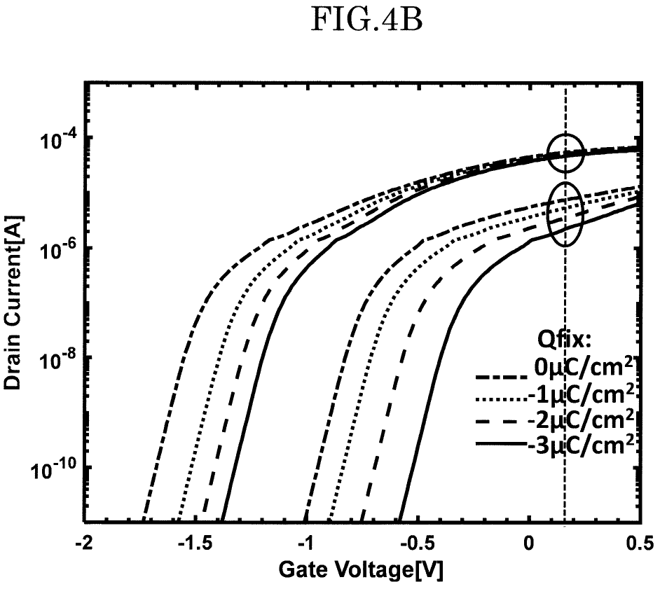

FIG. 4A is a graph showing the simulation results of an operating point analysis in the AFeFET model shown in FIG. 3A. The basic content is similar to that of FIG. 3C, but in FIG. 4A, the load curve 32 is shown for each of the cases where the gate voltage V_{g}-V_{FB} applied to the gate of the AFeFET model is −0.5 V, 1.25 V, and 3 V. In this case, the flat-band voltage VFB is −1 V. In addition, in FIG. 4A, the fixed charge is changed in a range of −3 μC/cm² to 0 μC/cm² for each load curve. In FIG. 4A, each load curve 32 has a region (hereinafter, referred to as “flat region”) below the curve where the charge density becomes constant with respect to a change in the first voltage (V_{AFe}). In the flat region 35, the MOS transistor operates in a sub-threshold region.

As shown in FIG. 4A, when the negative fixed charge increases, the flat region 35 of each load curve 32 shifts upward. This is thought to be because V_{MOS} decreases as the negative fixed charge increases. On the other hand, when the AFeFET is in the erase state, a read current is smaller than when it is in the program state. For example, taking the load curve 32 with V_{g}−V_{FB} of 1.25 V (the load curve 32 in the center of FIG. 4A) as an example, when the fixed charge is −3 μC/cm², the lower operating point 34 in the erase state is positioned near the flat region 35 of the load curve 32. That is, when the AFeFET is in the erase state, the operating point is positioned near the sub-threshold region, so that the drain current does not flow much. Conversely, the upper operating point 33 in the program state is positioned above the load curve 32, that is, far from the flat region 35. That is, when the AFeFET is in the program state, a large drain current flows.

As described above, when the negative fixed charge is increased, the flat region 35 of the load curve 32 moves upward, so that the read current in the AFeFET in the erase state tends to decrease, whereas the read current in the program state tends not to change as much as the read current in the erase state. That is, by increasing the negative fixed charge, a ratio between the drain current at the time of reading in the program state of the AFeFET and the drain current at the time of reading in the erase state (hereinafter referred to as “drain current ratio at the time of reading”) becomes large, and the discrimination of stored information (information of “1” or “0”) in the AFeFET is improved. Therefore, the gate insulating layer composed of the antiferroelectric material preferably has a fixed charge of −3 μC/cm² to 2 μC/cm², and more preferably has a fixed charge of −2 μC/cm² to −1 μC/cm². The reason why it is preferable to set the fixed charge in the gate insulating layer to −3 μC/cm² or more is that if the fixed charge is excessively present in the gate insulating layer from the viewpoint of reliability as a AFeFET, it may deteriorate.

Although the case where the flat region 35 of the load curve 32 is shifted upward by introducing the negative fixed charge into the gate insulating layer has been described, the shape of the polarization characteristic curve of the antiferroelectric material 31 may be changed. For example, in the case where zirconium oxide is used as the antiferroelectric material, the polarization characteristic curve 31 approaches the polarization characteristic curve of the ferroelectric material by adding hafnium. As a result, the lower operating point 34 in the erase state of the AFeFET approaches the flat region 35 of the load curve 32 as in the case of increasing the negative fixed charge, so that the drain current ratio at the time of reading can be increased.

Conventionally, in a nonvolatile memory element such as the FeFET, a difference between a threshold voltage in the program state and a threshold voltage in the erase state is defined as a memory window. However, in the AFeFET of the present embodiment, as described above, it is desirable to define the ratio between the drain current at the time of reading in the program state and the drain current at the time of reading in the erase state (that is, the drain current ratio at the time of reading) as the memory window. It is preferable that the gate voltage at the time of reading is set to a voltage at which the AFeFET is turned on in both the program state and the erase state. This is because, when the AFeFET is set to a voltage which turns it on in the program state and turns it off in the erase state and the memory cells in the same block are repeatedly read, there is a possibility that a phenomenon (so-called read disturb) occurs in which the data of the adjacent memory cells is rewritten.

Therefore, in order to appropriately evaluate the memory window in the AFeFET of the present embodiment, the present inventors have decided to define the drain current ratio at the time of reading as the memory window. That is, in FIG. 4A, the discriminability of the stored information is evaluated by using the drain current ratio when operating at a position where the vertical width of the hysteresis loop is largely open (for example, the position of the load curve 32 when V_{g}−V_{FB} is 1.25 V).

FIG. 4B is a graph showing the dependence of the Id-Vg characteristic on the fixed charge in the AFeFET model shown in FIG. 3A. In FIG. 4B, a straight line near the gate voltage of 0.16 V represents the gate voltage at the time of reading. In the present embodiment, in FIG. 4B, the drain current at the time of reading is obtained by using the drain current at the intersection of the straight line and an Id-Vg characteristic curve. Specifically, in the present embodiment, the drain current (the upper curve group in FIG. 4B) in the program state and the drain current (the lower curve group in FIG. 4B) in the erase state of the AFeFET model shown in FIG. 3A are evaluated as the memory window.

As shown in FIG. 4B, the drain current in the program state does not largely depend on the value of the fixed charge, while the drain current in the erase state depends on the value of the fixed charge. As a result, it was found that the memory window (the drain current ratio at the time of reading) of the AFeFET increased with the increase in the amount of negative fixed charges present inside or at the interface of the gate insulating layer. From this, it can be seen that, in order to secure the memory window, the gate insulating layer composed of the antiferroelectric material preferably has a fixed charge of −3 μC/cm² to 2 μC/cm², and more preferably has a fixed charge of −2 μC/cm² to −1 μC/cm².

[Adjustment by Interface Dipole] Next, an adjustment of the load curve 32 by the interface dipole will be described. The interface dipole is a dipole caused by an interface layer present between two layers. In the present embodiment, the interface layer is arranged between the gate insulating layer and the gate electrode, and the load curve 32 is shifted in the left-right direction by using the dipole caused by the interface layer. Specifically, in the present embodiment, the introduction of the interface dipole shifts the flat-band voltage of the AFeFET model shown in FIG. 3A and consequently shifts the load curve 32. For example, covalent silicon oxide (SiO₂) or germanium oxide (GeO₂) is used as the interface layer, and the dipole is formed by silicon oxide or germanium oxide and the gate insulating layer, which is a high dielectric constant material (High-k material).

In the present embodiment, since zirconium oxide is used as the gate insulating layer and silicon oxide is used as the interface layer, the dipole is formed of a stacked structure of silicon oxide and zirconium oxide. When the silicon oxide contacts the zirconium oxide, oxide ions move from the zirconium oxide having a large space density of oxygen atoms to the silicon oxide having a small space density of oxygen atoms, so that the zirconium oxide becomes oxygen-deficient and positively charged, and the silicon oxide is negatively charged. Therefore, a dipole in which the silicon-oxide side is negative and the zirconium-oxide side (the gate insulating layer side) is positive is generated.

In the present embodiment, since the relationship that the work function of the first material constituting the gate electrode is smaller than the work function of the second material constituting the oxide semiconductor is used, it is preferable to form a dipole having a negative value on the gate electrode side and a positive value on the semiconductor layer side. That is, in the present embodiment, a structure is used in which a layer composed of silicon oxide is arranged as the interface layer between the gate insulating layer, which is zirconium oxide, and the gate electrode. That is, the AFeFET of the present embodiment has a stacked structure composed of oxide semiconductor, zirconium oxide, silicon oxide, and the gate electrode.

As described above, the flat band voltage of the AFeFET can be shifted by arranging silicon oxide (or germanium oxide) as the interface layer between the gate insulating layer (zirconium oxide) and the gate electrode and forming the dipole due to the interface layer. This allows the load curve 32 shown in FIG. 3C to be shifted and the position of the operating point of the AFeFET to be adjusted appropriately. A thickness of the interface layer is preferably 0.5 nm or more and 5 nm or less, and more preferably 1 nm or more and 2 nm or less. The interface layer is preferably formed by an ALD method.

[Device Structure] Hereinafter, a structure of an antiferroelectric memory device 100 according to an embodiment of the present invention will be described.

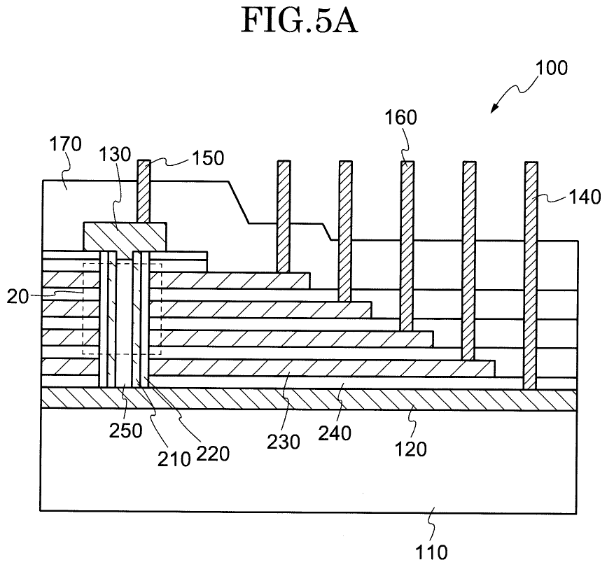

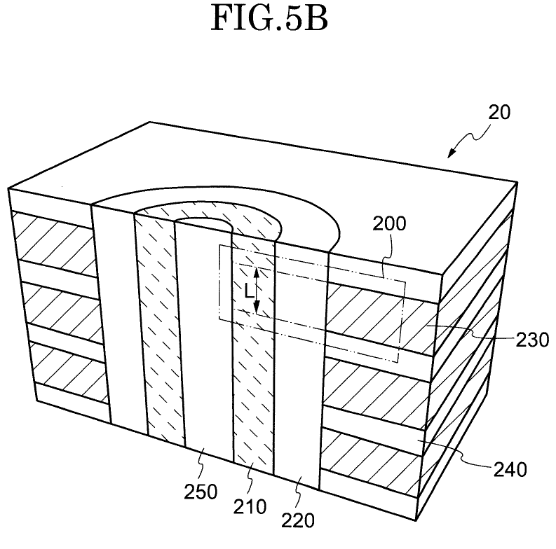

FIG. 5A is a cross-sectional view showing a device structure of the antiferroelectric memory device 100 according to an embodiment of the present invention. The antiferroelectric memory device 100 shown in FIG. 5A has a three-dimensional stacked structure in which a plurality of antiferroelectric memory elements 20 (see FIG. 5B) is three-dimensionally integrated. The plurality of antiferroelectric memory elements 20 share a cylindrical semiconductor layer 210 that functions as a channel, and is arranged in series along the longitudinal direction of the semiconductor layer 210. In the present embodiment, the antiferroelectric memory element 20 is the AFeFET having a gate insulating layer 220 composed of the antiferroelectric material.

A source electrode 120 is arranged on a substrate 110. A silicon substrate having an insulating surface, a metal substrate, or the like can be used as the substrate 110. A metal material containing titanium, aluminum, tungsten, tantalum, molybdenum, copper, or the like, or a compound material containing these metal materials can be used as the source electrode 120. In the case where an n-type semiconductor substrate (for example, an n-type silicon substrate) is used as the substrate 110 to function as a source, the source electrode 120 shown in FIG. 5A may be omitted.

The plurality of antiferroelectric memory elements 20 is arranged in series between the source electrode 120 and a drain electrode 130. The semiconductor layer 210 is electrically connected to the source electrode 120 and the drain electrode 130. That is, in the antiferroelectric memory device 100, the plurality of antiferroelectric memory elements 20 also share the source electrode 120 and the drain electrode 130.

The source electrode 120 is electrically connected to a source terminal 140 composed of a metal material. The drain electrode 130 is electrically connected to a drain terminal 150 composed of a metal material. The drain terminal 150 is connected to a bit line (not shown) of the antiferroelectric memory device 100. In addition, the plurality of gate electrodes 230 is electrically connected to a gate terminal 160, respectively. The plurality of gate terminals 160 is connected to a word line (not shown) of the antiferroelectric memory device 100. The source terminal 140, the drain terminal 150, and the gate terminal 160 are electrically connected to the source electrode 120, the drain electrode 130, and the gate electrode 230, respectively, via contact holes arranged in a passivation layer 170, insulating layers 240 arranged between each of the gate electrodes 230, or an insulating layer 240 provided between the lowest gate electrode 230 and the source electrode 120.

FIG. 5B is a cross-sectional perspective view of the antiferroelectric memory device 100 according to an embodiment of the present invention. Specifically, FIG. 5B is an enlarged view of a portion (a portion corresponding to the three antiferroelectric memory elements 20) surrounded by a frame line 200 in the antiferroelectric memory device 100 shown in FIG. 5A.

As shown in FIG. 5B, the antiferroelectric memory element 20 of the present embodiment is an AFeFET composed of the semiconductor layer 210, the gate insulating layer 220, and the gate electrode 230. In the antiferroelectric memory device 100 of the present embodiment, the plurality of antiferroelectric memory elements 20 shares the semiconductor layer 210 and the gate insulating layer 220.

The semiconductor layer 210 is a cylindrical member that functions as a channel of the antiferroelectric memory element 20. In the present embodiment, the semiconductor layer 210 includes a metal oxide. Specifically, the semiconductor layer 210 is composed of indium oxide (InOₓ). A thickness of the semiconductor layer 210 is 5 nm or more and 15 nm or less (preferably 8 nm or more and 10 nm or less). In addition, in the present embodiment, the semiconductor layer 210 is formed by the ALD (Atomic Layer Deposition) method. However, other methods may be used as long as the semiconductor layer 210 can be formed with a uniform thickness on an inner wall of a trench.

The semiconductor layer 210 is not limited to indium oxide, and other metal oxides may be used. For example, a metal oxide called IGZO may be used as the semiconductor layer 210. IGZO is a metal oxide that exhibits semiconductor properties, and is a compound material composed of indium, gallium, zinc, and oxygen. Namely, IGZO is an oxide comprising In, Ga, and Zn or a mixture of such oxides. The composition of IGZO is preferably In₂₋ₓGaₓO₃(ZnO)ₘ (0<x<2, where m is a natural number less than 6), more preferably InGaO₃(ZnO)ₘ (where m is a natural number less than 6), and most preferably InGaO₃(ZnO). In addition, tin oxide (SnO₂), IZO (metal oxide including In and Zn), zinc oxide (ZnO), and the like can be used.

In addition, the semiconductor layer 210 is not limited to a single-layer structure, and may be a stacked structure. For example, a semiconductor layer having a stacked structure composed of a first semiconductor layer and a second semiconductor layer having a wider band gap than the first semiconductor layer may be used.

The gate insulating layer 220 is composed of the antiferroelectric material. Specifically, in the present embodiment, zirconium oxide (ZrO₂) is used as the antiferroelectric material constituting the gate insulating layer 220. However, the antiferroelectric material that can be used in the present embodiment is not limited to zirconium oxide, and other materials exhibiting antiferroelectric properties may be used. In addition, a material obtained by adding hafnium to zirconium oxide may be used as the gate insulating layer 220. By using a composite oxide in which part of zirconium of zirconium oxide is replaced with hafnium, the shape of the polarization characteristic curve (butterfly curve) of zirconium oxide can be changed. For example, in HfₓZr₁₋ₓO₂, preferably 0≤x<0.5, more preferably 0≤x≤0.4, and most preferably 0≤x≤0.3.

In the present embodiment, the gate insulating layer 220 is formed to a thickness of 10 nm by the ALD method. However, the thickness of the gate insulating layer 220 is not limited to this example, and may be, for example, 5 nm or more and 20 nm or less (preferably, 8 nm or more and 18 nm or less). The gate insulating layer 220 is arranged so as to surround the semiconductor layer 210 in contact with a side surface of the semiconductor layer 210. That is, the gate insulating layer 220 may be a cylindrical member having a cylindrical semiconductor layer 210 inside. The gate insulating layer 220 of the present embodiment has a fixed charge of −3 μC/cm² to 2 μC/cm² (preferably a fixed charge of −2 μC/cm² to −1 μC/cm²).

The gate electrode 230 functions as a gate for controlling the programming operation or erase operation of the antiferroelectric memory element 20. In the present embodiment, n-type doped silicon (n-type silicon) is used as the gate electrode 230. In the antiferroelectric memory element 20 of the present embodiment, a width of the gate electrode 230 corresponds to a channel length (L) of the antiferroelectric memory element 20. The width of the gate electrode 230 is the thickness of the n-type polysilicon layer functioning as the gate electrode 230. In this case, in the present embodiment, a material having an electron affinity (that is, a work function) smaller than the electron affinity of the material constituting the semiconductor layer 210 is used as a material constituting the gate electrode 230.

A gate-first method is preferably used to form the gate electrode 230. In the present embodiment, an n-type polysilicon layer used as the gate electrode 230 and the insulating layer such as silicon oxide used as the insulating layer 240 are alternately stacked on a substrate to form a stacked structure, and then a plurality of vertical trenches (memory holes) is formed in the stacked structure. After the plurality of trenches is formed, the gate insulating layer 220 and the semiconductor layer 210 are sequentially stacked on the inner wall thereof. Finally, an insulating material used as a filler member 250 is filled in the hollow portion of the semiconductor layer 210. In this case, lithography and reactive ion etching can be used to form the trench.

In the case where a metal material is used as the gate electrode 230, a gate-last method may be used. In the gate-last method, first, a dummy layer made of silicon nitride or the like and an insulating layer made of silicon oxide or the like are alternately stacked to form a stacked structure, and then a plurality of vertical trenches (memory holes) is formed in the stacked structure. Thereafter, the dummy layer is selectively removed, and a metal material is embedded in the space from which the dummy layer is removed, thereby forming a gate electrode made of a metal material. The gate insulating layer 220 and the semiconductor layer 210 are formed in the same manner as in the gate-first method. It is also possible to form the above-described interface layer by embedding the metal material and then embedding silicon oxide or germanium oxide in contact with the metal material. However, the present invention is not limited to this, and the plurality of trenches may be formed, and then the interface layer, the gate insulating layer 220, and the semiconductor layer 210 may be sequentially stacked on the inner wall thereof.

The insulating layer 240 is an insulating film for insulating the space between the two gate electrodes 230 adjacent to each other. An insulating film such as a silicon oxide film or a silicon nitride film can be used as the insulating layer 240. In the present embodiment, a thickness of the insulating layer 240 is 10 nm or more and 50 nm or less (preferably 20 nm or more and 40 nm or less), but is not limited to this example. The thickness of the insulating layer 240 may be appropriately determined according to the relationship with the channel length (that is, the width of the gate electrode 230). However, if the thickness of the insulating layer 240 is too thin, the adjacent antiferroelectric memory elements 20 may affect each other and cause an operation failure. In addition, if the thickness of the insulating layer 240 is too thick, the distance between the channels of the adjacent antiferroelectric memory elements 20 becomes long, which may become a barrier to carrier movement.

The filler member 250 functions as a filler that fills the inside of the cylindrical semiconductor layer 210. An insulating material such as silicon oxide, silicon nitride, or resin can be used as the filler member 250. These insulating materials can be filled inside the semiconductor layer 210 by known methods such as CVD. In the case where a trench (memory hole) diameter is small, the filler member 250 may not be present, in which case the semiconductor layer 210 is columnar rather than cylindrical. The filler member 250 does not need to completely fill the inside of the cylindrical semiconductor layer 210, and a space that is not filled with the filler member may remain in part of the inside of the semiconductor layer 210.

The antiferroelectric memory device 100 of the present embodiment described above is composed of the antiferroelectric memory element 20 in which an oxide semiconductor is used as the semiconductor layer 210 and an antiferroelectric material is used as the gate insulating layer 220. The antiferroelectric memory element using the oxide semiconductor has an advantage of low power consumption and high reliability, but has a disadvantage that the erase operation tends to be insufficient, as described in the conventional techniques. However, in the antiferroelectric memory device 100 of the present embodiment, the above-described disadvantage is overcome, and a stable erase operation is realized by combining the oxide semiconductor and the antiferroelectric material and selectively using the positive-side hysteresis loop (plus loop) of the polarization characteristic curves of the antiferroelectric material.

[Examples] Hereinafter, the measurement results of a structure and electrical characteristics of a prototype antiferroelectric memory device 300 of the present embodiment will be described.

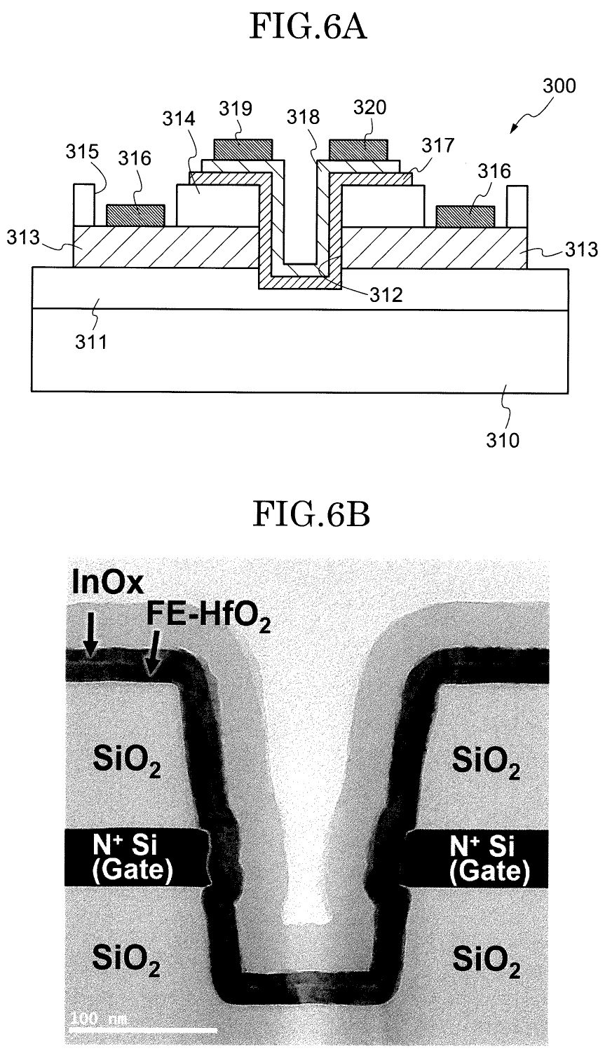

FIG. 6A is a cross-sectional view showing a structure of the antiferroelectric memory device 300 according to an embodiment of the present invention. The antiferroelectric memory device 300 shown in FIG. 6A has a structure in which two antiferroelectric memory elements of a vertical type (a type in which a channel extends in the direction perpendicular to a substrate) are connected in series.

In FIG. 6A, a base layer 311 composed of silicon oxide is arranged on a silicon substrate 310. Two gate electrodes 313 are arranged on the base layer 311 so as to face each other across a trench 312, and an interlayer insulating layer 314 is arranged on the gate electrodes 313. Openings 315 are formed in the interlayer insulating layer 314, and gate terminals 316 electrically connected to the gate electrodes 313 are arranged inside the openings 315.

A gate insulating layer 317 composed of zirconium oxide and a semiconductor layer 318 composed of indium oxide are sequentially stacked on an inner wall of the trench 312. A source terminal 319 is electrically connected to one end of the semiconductor layer 318, and a drain terminal 320 is electrically connected to the other end of the semiconductor layer 318.

The antiferroelectric memory device 300 having the above structure has two antiferroelectric memory elements having a structure in which the gate electrodes 313 and the semiconductor layer 318 face each other across the gate insulating layer 317 inside the trench 312.

A method for manufacturing the antiferroelectric memory device 300 shown in FIG. 6A will be briefly described. First, an SOI substrate was prepared, phosphorus (P) was added to a silicon layer on a box-oxide film by ion implantation, and then phosphorus was electrically activated. As a result, an n-type silicon layer was formed on the silicon substrate (the silicon substrate 310) via the box-oxide film (the base layer 311). After forming the n-type silicon layer, the n-type silicon layer was subjected to a thermal oxidation treatment to reduce a thickness of the n-type silicon layer. In this case, a thermal oxide film formed by the thermal oxidation treatment was left as it was and used as the interlayer insulating layer 314.

After the thermal oxidation treatment of the n-type silicon layer, a through hole penetrating the thermal oxide film and the n-type silicon layer and reaching the box-oxide film was formed. The through hole corresponds to the trench 312 shown in FIG. 6A. The trench 312 was formed by combining a patterning process by electron-beam lithography system and an RIE (Reactive Ion Etching) process.

After the trench 312 was formed, the n-type silicon layer and the thermal oxide film were patterned to form an island-shape pattern. The gate electrode 313 and the interlayer insulating layer 314 shown in FIG. 6A correspond to the patterned n-type silicon layer and thermal oxide film, respectively. The patterned n-type silicon layer and the thermal oxide film are separated into two by the trench 312. That is, at this point, two patterned n-type silicon layers and two thermal oxide films are formed.

After the patterning of the n-type silicon layer and the thermal oxide film was completed, the gate insulating layer 317 composed of the antiferroelectric material was formed inside the trench 312. A 10 nm zirconium oxide layer was formed by the ALD method as the gate insulating layer 317. Deposition was performed at room temperature. Next, patterning was performed by etching, and after patterning, an RTA (Rapid Thermal Anneal) at 600° C. was performed on the gate insulating layer 317. This annealing was performed to crystallize the gate insulating layer 317.

After the gate insulating layer 317 was crystallized, a 10 nm indium oxide layer was formed on the gate insulating layer 317 by the ALD method as the semiconductor layer 318 composed of the oxide semiconductor. Deposition was performed at 200° C. Next, patterning was performed by etching, and after patterning, a heat treatment was performed with respect to the semiconductor layer 318 at 200° C. in an ozone atmosphere. This heat treatment was carried out in order to reduce oxygen vacancies of the semiconductor layer 318 and improve the function as a semiconductor.

After the semiconductor layer 318 was formed, the source terminal 319 and the drain terminal 320 were formed. The source terminal 319 and the drain terminal 320 were formed by patterning a titanium nitride layer. Next, the openings 315 was formed in the interlayer insulating layer 314, and the gate terminals 316 were formed inside the openings 315. The gate terminals 316 were formed by patterning a stacked structure of a titanium nitride layer and a titanium layer.

FIG. 6B is a cross-sectional TEM photograph in the vicinity of the trench of the prototype ferroelectric memory device. Although a ferroelectric hafnium oxide layer (HfO₂) is used as the gate insulating layer in FIG. 6B, in the above-described antiferroelectric memory device 300, a zirconium oxide layer is used instead of the hafnium oxide layer. As shown in FIG. 6B, since the ALD method is used as the deposition method of the gate insulating layer 317 and the semiconductor layer 318, the film is deposited on the inner wall surface of the trench with a uniform thickness. The uniform thickness of the gate insulating layer 317 and the semiconductor layer 318 is desirable for achieving stable memory operation.

Next, the electrical characteristics of the prototype antiferroelectric memory device 300 manufactured by the above-described manufacturing method will be described. In addition, since the antiferroelectric memory device 300 shown in FIG. 6A has two antiferroelectric memory elements connected in series, one antiferroelectric memory element was turned on and the other antiferroelectric memory element was measured for electrical characteristics.

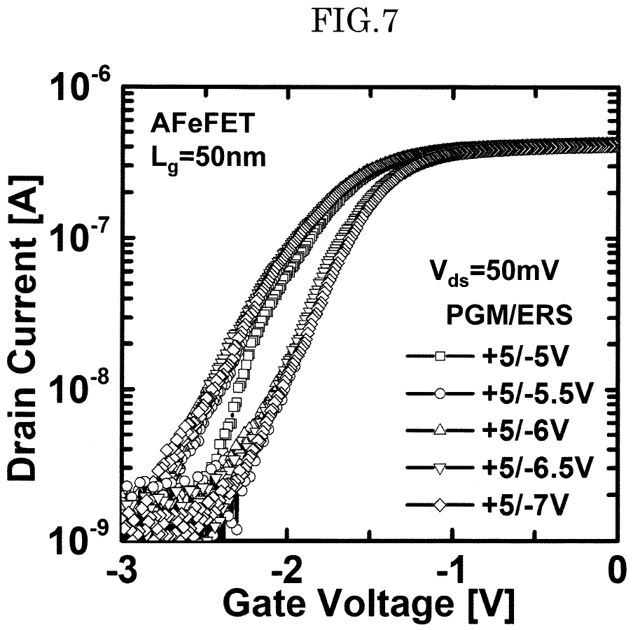

FIG. 7 is a graph showing an Id-Vg characteristic measured using the antiferroelectric memory device 300 according to an embodiment of the present invention. A channel length (Lg) of the antiferroelectric memory device 300 is 50 nm, and a gate width (a length of the gate electrode 313 in a depth direction in FIG. 6A) is 20 μm. A source-drain voltage (Vds) was 50 mV. The gate voltage (V_{g}) was swept in a range (−3 V to 0 V) where no erase/program operation occurred. In addition, a program voltage (PGM) was uniformly set to +5 V. The Id-Vg characteristic was measured for an erase voltage (ERS) of each of −5 V, −5.5 V, −6 V, −6.5 V, and −7 V. As a result, it was confirmed that the prototype antiferroelectric memory device 300 can realize the memory operation normally without depending almost on the erase voltage.

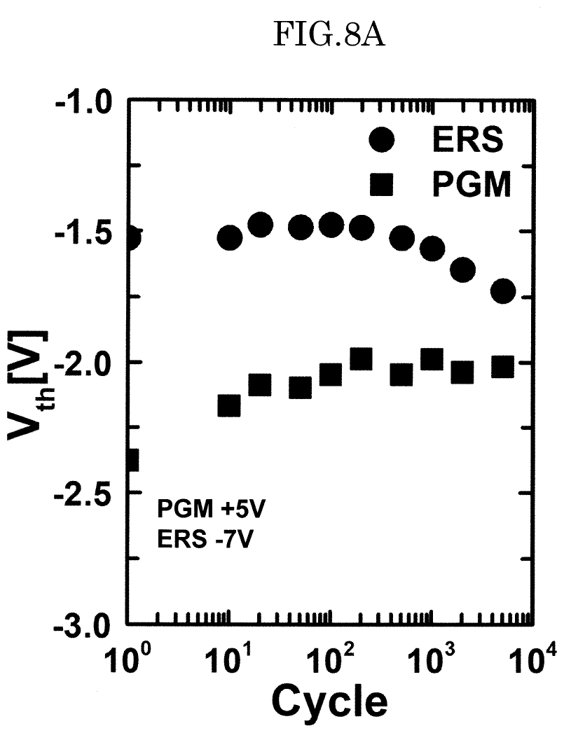

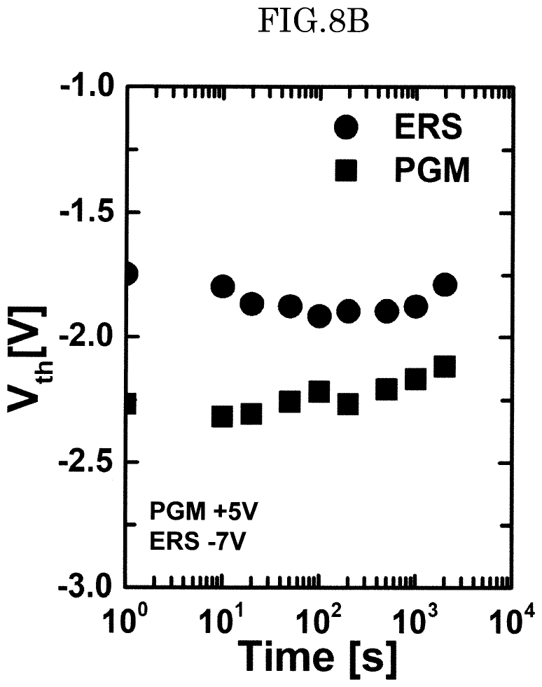

FIG. 8A is a graph showing results of measuring a rewrite endurance of the antiferroelectric memory device 300 at room temperature according to an embodiment of the present invention. The horizontal axis represents a cycle of stress, and the vertical axis represents a threshold voltage. A point indicated by a square dot is a value when the program voltage (+5 V) is applied, and a point indicated by a round dot is a value when the erase voltage (−7 V) is applied. As shown in FIG. 8A, it was found that the prototype antiferroelectric memory device 300 exhibited a stable rewrite endurance of up to about 1×10³ times.

FIG. 8B is a graph showing the results of measuring a retention characteristic of the antiferroelectric memory device 300 at room temperature according to an embodiment of the present invention. The horizontal axis represents time, and the vertical axis represents a threshold voltage. A point indicated by a square dot is a value when the program voltage (+5 V) is applied, and a point indicated by a round dot is a value when the erase voltage (−7 V) is applied. As shown in FIG. 8B, it was found that the prototype antiferroelectric memory device 300 exhibited a stable retention characteristic up to about 1×10³ sec.

[Simulation Results] The present inventors simulated the dependence of the electrical characteristics on various parameters based on the AFeFET model shown in FIG. 3A. Hereinafter, each simulation result will be described. In the following description, the definitions of the terms memory window and operating point are as described above. That is, the memory window refers to the ratio of the drain current (read current) in the program state to the drain current in the erase state (that is, the drain current ratio in the read state) in the AFeTFT model. In addition, the operating point refers to an intersection of the polarization characteristic curve of the antiferroelectric capacitor and the load curve of the MOS transistor in the AFeTFT model.

First, the results of simulating the dependence of the electrical characteristics on the carrier density (N_{d}) based on the AFeFET model will be described.

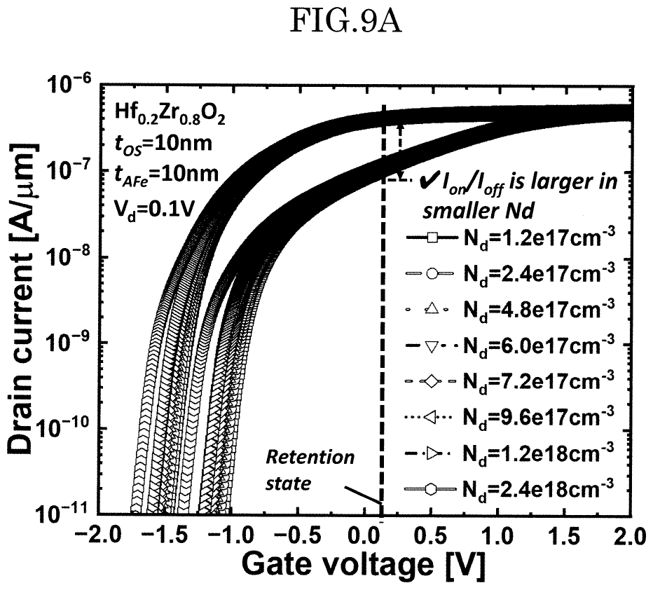

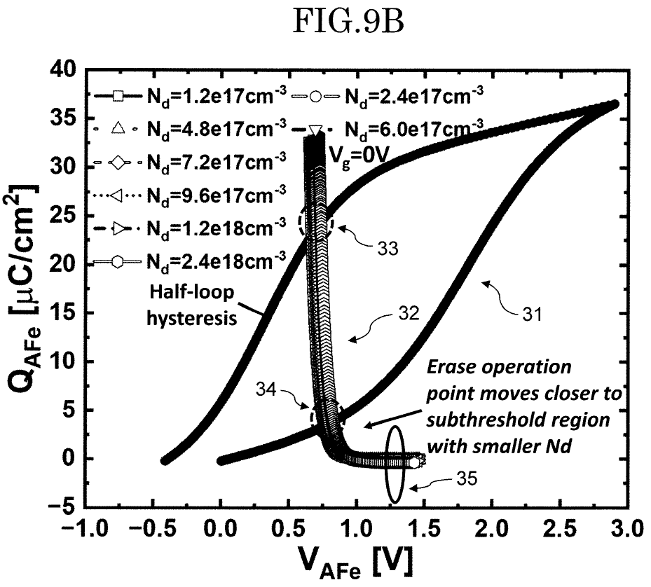

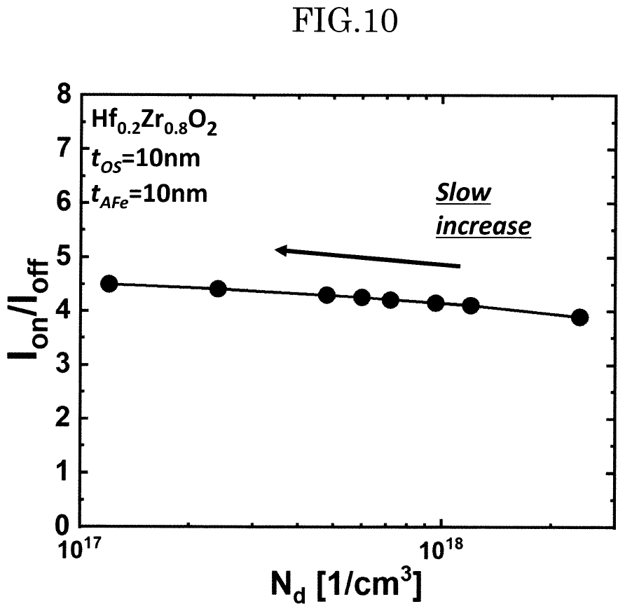

FIG. 9A is a graph showing the simulation results of an Id-Vg characteristic when the carrier density (N_{d}) is changed in the AFeFET model. FIG. 9B is a graph showing the simulation results of an operating point analysis when the carrier density (N_{d}) is changed in the AFeFET model. FIG. 10 is a graph showing the dependence of the memory window on the carrier density (N_{d}) in the AFeFET model.

The conditions of the simulation are basically the same as the conditions used for the simulation of the AFeFET model shown in the above-described FIG. 3A. For example, the gate length and the gate width were set to 50 μm, respectively, and the source-drain voltage (Vds) was set to 0.1 V. In addition, the composition of the antiferroelectric material used as the gate insulating layer was Hf_{0.2}Zr_{0.8}O_{0.2}. That is, a complex oxide in which a part (20 mol %) of zirconium in zirconium oxide was replaced with hafnium was used as the gate insulating layer. A thickness (t_{AFe}) of the gate insulating layer (the antiferroelectric layer) and a thickness (t_{OS}) of the channel (the oxide semiconductor layer) were 10 nm, respectively. In addition, −1.0 V was set as the flat-band voltage (V_{FB}). On the other hand, the carrier density (N_{d}) was set to be lower than 1×10¹⁹ cm⁻³, specifically 1.2×10¹⁷ cm⁻³, 2.4×10¹⁷ cm⁻³, 4.8×10¹⁷ cm⁻³, 6.0×10¹⁷ cm⁻³, 7.2×10¹⁷ cm⁻³, 9.6×10¹⁷ cm⁻³, 1.2×10¹⁸ cm⁻³ or 2.4×10¹⁸ cm⁻³, which is the condition used for simulating the AFeFET model shown in the above-described FIG. 3A.

As shown in FIG. 9A and FIG. 10, a slow increase in the difference between the drain current in the program state and the drain current in the erase state is observed as the carrier density (N_{d}) decreases, and the memory window slightly increases. The reason why the memory window increases is that the amount of change in which the drain current in the erase state decreases is larger than the amount of change in which the drain current in the program state decreases.

As shown in FIG. 9B, since the load curve 32 shifts leftward (in the negative direction) as the carrier density (N_{d}) decreases, the upper operating point 33 in the program state and the lower operating point 34 in the erase state also shift leftward. In this case, since the lower operating point 34 approaches the sub-threshold region (that is, approaches the flat region 35 of the load curve 32) in the erase state, the charge balance is maintained at a low charge density, resulting in a low drain current. As described above, as the carrier density (N_{d}) decreases, the drain current in the erase state decreases significantly as compared with the drain current in the program state, so that the drain current ratio at the time of reading, that is, the memory window, increases.

Next, the simulation results of the dependence of the electrical characteristics on the thickness (t_{OS}) of the channel (the oxide semiconductor layer) based on the AFeFET model will be described.

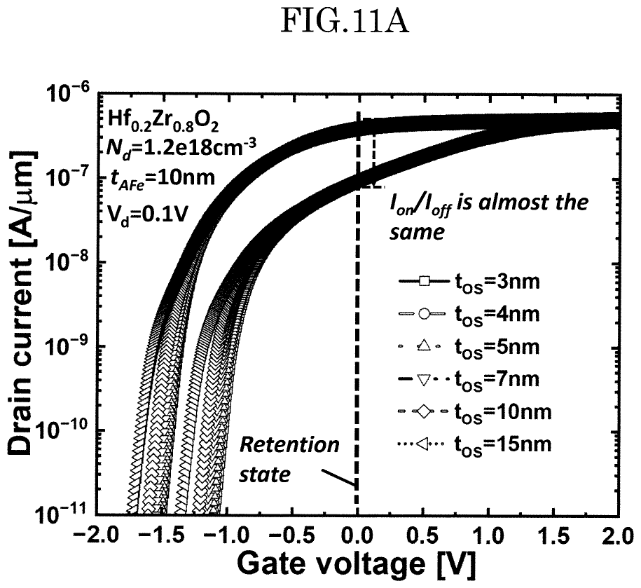

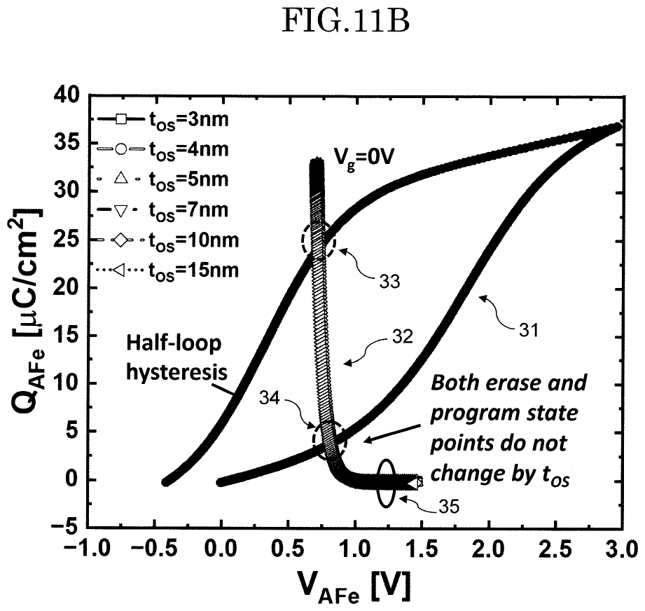

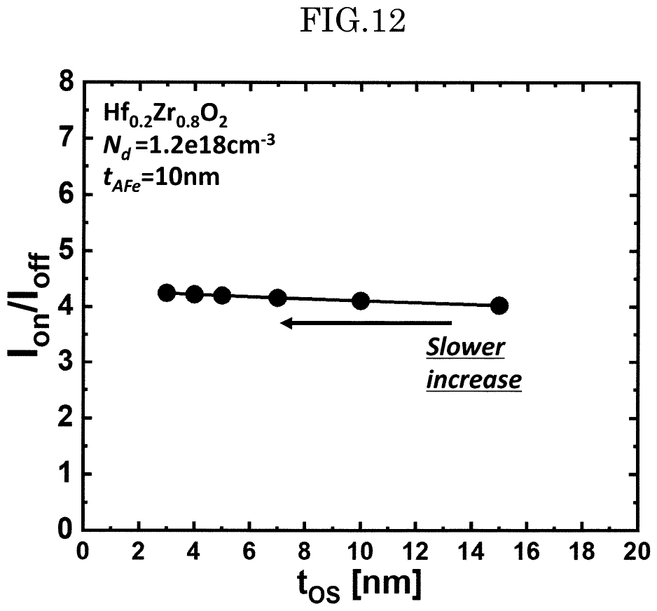

FIG. 11A is a graph showing the simulation results of an Id-Vg characteristic of when the thickness of the oxide semiconductor layer is changed in the AFeFET model. FIG. 11B is a graph showing the simulation results of the operating point analysis when the thickness of the oxide semiconductor layer is changed in the AFeFET model. FIG. 12 is a graph showing the dependence of the memory window on the thickness of the oxide semiconductor layer in the AFeFET model.

The conditions of the simulation are basically the same as the conditions of the simulation described with reference to FIG. 9A and FIG. 9B. However, the carrier density (N_{d}) was fixed at 1.2×10¹⁸ cm⁻³. In addition, the thickness (t_{OS}) of the oxide semiconductor layer was set to 3nm, 4 nm, 5 nm, 7 nm, 10 nm, or 15 nm.

As shown in FIG. 11A and FIG. 12, it was found that the difference between the drain current in the program state and the drain current in the erase state slightly increased with the decrease in the thickness (t_{OS}) of the oxide semiconductor layer, and the memory window slower increased. In addition, as shown in FIG. 11B, even if the thickness (t_{OS}) of the oxide semiconductor layer changed, almost no shift was observed in the position of the load curve 32, and no significant change was observed in the positions of the upper operating point 33 in the program state and the lower operating point 34 in the erase state. Therefore, it was found that the thickness of the oxide semiconductor layer had little effect on the memory window in the AFeFET model.

Next, the simulation results of the dependence of the electrical characteristics on the thickness (t_{AFe}) of the gate insulating layer (the antiferroelectric layer) based on the AFeFET model will be described.

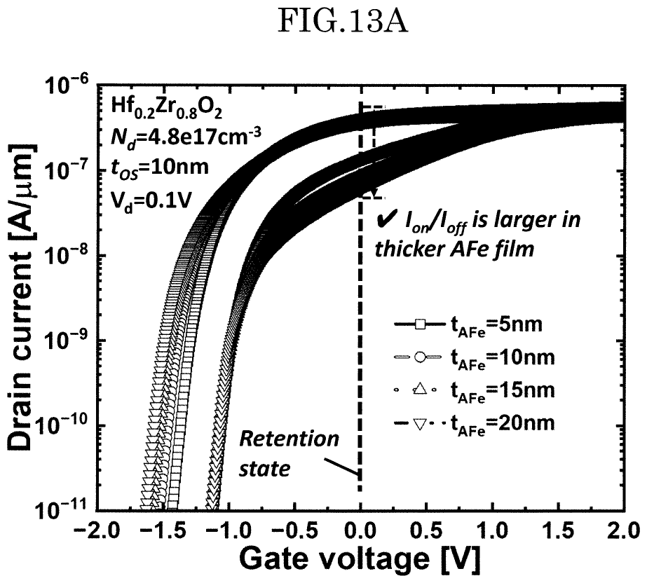

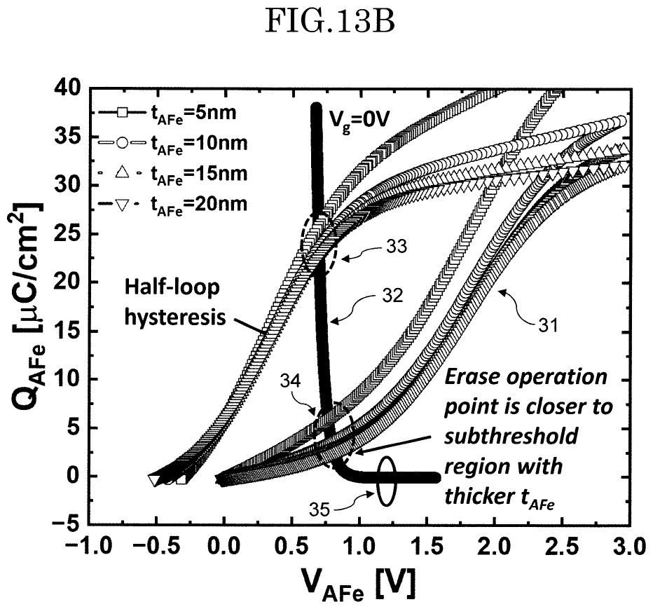

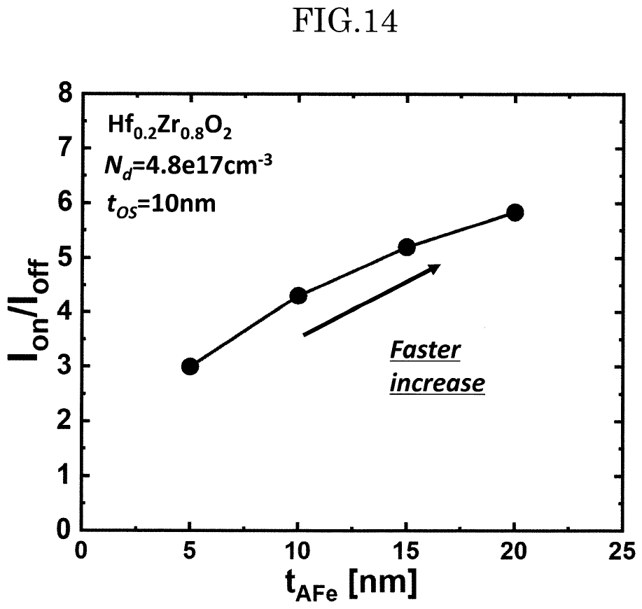

FIG. 13A is a graph showing the simulation results of an Id-Vg characteristic when the thickness of the antiferroelectric layer is changed in the AFeFET model. FIG. 13B is a graph showing the simulation results of the operating point analysis when the thickness of the antiferroelectric layer is changed in the AFeFET model. FIG. 14 is a graph showing the dependence of the memory window on the thickness of the antiferroelectric layer in the AFeFET model.

The conditions of the simulation are basically the same as the conditions of the simulation described with reference to FIG. 9A and FIG. 9B. However, the carrier density (N_{d}) was fixed at 4.8×10¹⁷ cm⁻³. The thickness (t_{AFe}) of the antiferroelectric layer was set to 5 nm, 10 nm, 15 nm or 20 nm.

As shown in FIG. 13A and FIG. 14, it was found that, as the thickness (t_{AFe}) of the antiferroelectric layers increases, the difference between the drain current in the program state and the drain current in the erase state increases, and the memory window faster increases. In particular, the results shown in FIG. 13A indicate a significant drop in the drain current in the erase state.

As shown in FIG. 13B, in the case where the thickness (t_{AFe}) of the antiferroelectric layer increased, no change is observed in the position of the load curve 32, and it can be seen that the polarization characteristic curve 31 shifts downward. As the thickness of the antiferroelectric layer increases, a paraelectric component of the antiferroelectric capacitor decreases and the polarization characteristic curve 31 shifts downward. As a result, the upper operating point 33 in the program state and the lower operating point 34 in the erase state both shift downward. In this case, since the lower operating point 34 approaches the sub-threshold region in the erase state, the charge balance is maintained at a low charge density, resulting in a low drain current.

As described above, since the drain current in the erase state significantly decreases as compared with the drain current in the program state as the thickness (t_{AFe}) of the antiferroelectric layer increases, the memory window becomes larger. From the above, it can be said that the thickness (t_{AFe}) of the gate insulating layer (the antiferroelectric layer) is preferably 5 nm or more and 50 nm or less, more preferably 8 nm or more and 30 nm or less, and most preferably 10 nm or more and 20 nm or less.

Next, the simulation results of the dependence of the electrical characteristics on the composition of the antiferroelectric material based on the AFeFET model will be described.

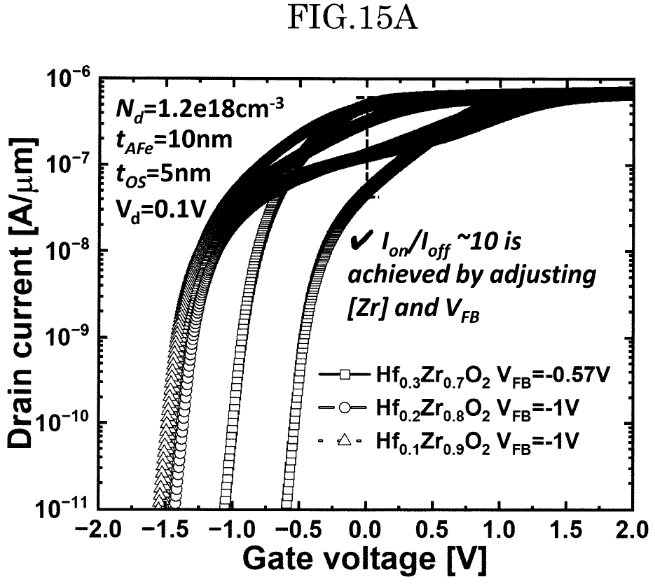

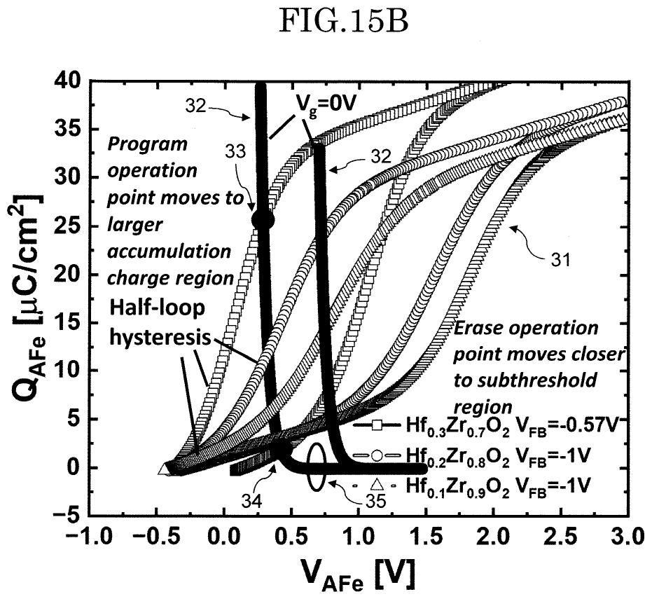

FIG. 15A is a graph showing the simulation results of an Id-Vg characteristic when the composition of the antiferroelectric material is changed in the AFeFET model. FIG. 15B is a graph showing the simulation results of the operating point analysis when the composition of the antiferroelectric material is changed in the AFeFET model. Note that two load curves 32 are shown in FIG. 15B, which will be explained later.

The conditions of the simulation are basically the same as the conditions of the simulation described with reference to FIG. 9A and FIG. 9B. However, the carrier density (N_{d}) was fixed at 1.2×10¹⁸ cm⁻³, and the thickness (t_{OS}) of the oxide semiconductor layer was fixed at 5 nm. The composition of the antiferroelectric material was Hf_{0.1}ZrO_{0.9}O₂, Hf_{0.2}Zr_{0.8}O₂ or Hf_{0.3}Zr_{0.7}O₂. That is, the total amount of zirconium in the zirconium oxide as the antiferroelectric material was set to 100 mol %, and the composite oxide in which 10 mol %, 20 mol %, or 30 mol % of the total amount of zirconium was replaced with hafnium was used. In addition, −0.5 V and −1.0 V are selectively used for the flat-band voltage (V_{FB}).

As shown in FIG. 15A, when the composition of the antiferroelectric material is changed, the Id-Vg characteristic also changes. Specifically, it was found that the smaller the zirconium content in the antiferroelectric material, the more the Id-Vg characteristic shifted to the right (the positive direction). In addition, as shown in FIG. 15B, it was found that the smaller the zirconium content in the antiferroelectric material, the more the polarization characteristic curve 31 shifted to the left (the negative direction). However, in FIG. 15B, in the case of Hf_{0.2}Zr_{0.8}O₂ and Hf_{0.1}Zr_{0.9}O₂, the flat-band voltage was set to −1.0 V, and in the case of Hf_{0.3}Zr_{0.7}O₂, the flat-band voltage was set to −0.5 V. In the case where the zirconium content is 80 mol % and 90 mol %, the flat-band voltage needs to be set to −1.0 V in order to obtain V_{g}=0 V. However, in the case where the zirconium content is 70 mol %, since the polarization characteristic curve 31 is shifted to the left as a whole, the flat band voltage of −0.5 V is sufficient.

A small absolute value of the flat-band voltage means that the work-function difference between the material of the gate electrode and the material of the oxide semiconductor is small. In other words, when the zirconium content in the gate insulating layer is reduced, there is an advantage in that options for combinations of the gate electrode material and the oxide semiconductor material increase when setting the appropriate work function difference.

As shown in FIG. 15B, in the case where the zirconium content is 70 mol %, the upper operating point 33 in the program state shifts upward, so that the drain current increases in the accumulated charge region. Conversely, since the lower operating point 34 in the erase state shifts downward, it approaches the sub-threshold region, and the drain current becomes smaller. Therefore, since the difference between the drain current in the program state and the drain current in the erase state becomes large, the memory window becomes large.

As described above, it was found that the memory window tends to increase as the zirconium content in the gate insulating layer decreases. In particular, the simulation results shown in FIG. 15A and FIG. 15B show that the drain current ratio at the time of reading, which is the memory window, is 10 or more when the zirconium content is 70 mol %. However, it is known that when the zirconium content decreases, it gradually exhibits the ferroelectric characteristics rather than the antiferroelectric characteristics. Therefore, in view of the options for combinations of the material of the gate electrode and the material of the oxide semiconductor, in HfₓZr₁₋ₓO₂ of the gate insulating layer (antiferroelectric layer), 0.1≤x≤0.4 is preferable, 0.15≤x≤0.35 is more preferable, and 0.2≤x≤0.3 is most preferable.

Next, the simulation results of the dependence of the electrical characteristics on the fixed electric charge based on the AFeFET model will be described.

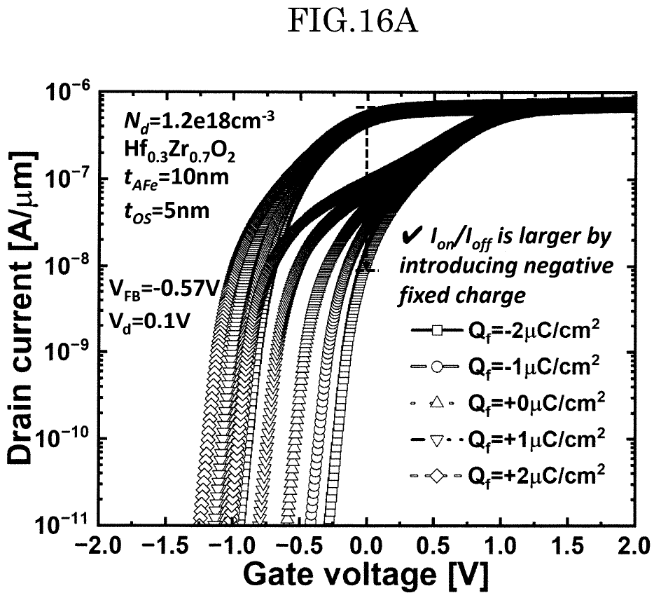

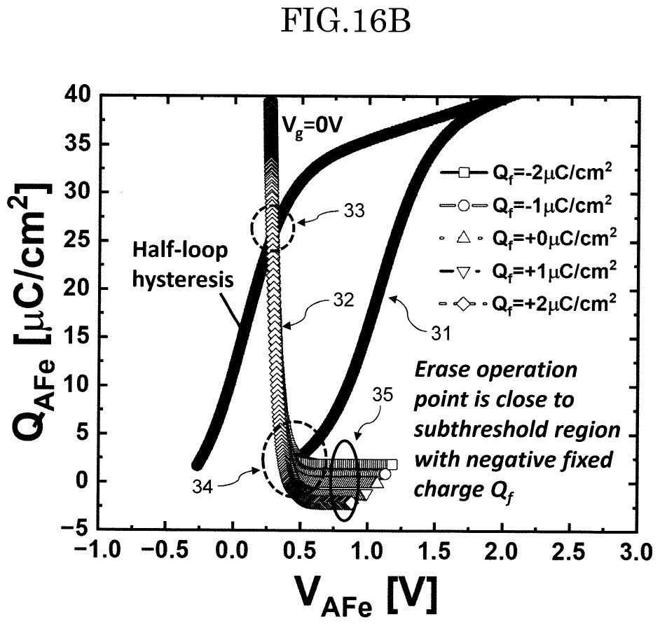

FIG. 16A is a graph showing the simulation results of an Id-Vg characteristic when the fixed charge is changed in the AFeFET model. FIG. 16B is a graph showing the simulation results of the operating point analysis when the fixed charge is changed in the AFeFET model.

The conditions of the simulation are basically the same as the conditions of the simulation described with reference to FIG. 9A and FIG. 9B. However, the carrier density (N_{d}) was fixed at 1.2×10¹⁸ cm⁻³, the antiferroelectric composition was Hf_{0.3}Zr_{0.7}O₂, and the thickness (t_{OS}) of the oxide semiconductor layer was fixed at 5 nm. In addition, the flat-band voltage was set to −0.57 V. A fixed charge (Q_{f}) was set at −2 μC/cm², −1 μC/cm², 0 μC/cm², 1 μC/cm², or 2 μC/cm².

As shown in FIG. 16A, the smaller the fixed charge (the larger the absolute value of the negative fixed charge), the more the Id-Vg characteristic shifts to the right (the positive direction). In addition, as shown in FIG. 16B, the smaller the fixed charge, the more the flat region 35 of the load curve 32 shifts upward. Therefore, since the lower operating point 34 in the erase state approaches the sub-threshold region, the drain current in the erase state becomes small. From the above, it is possible to read the tendency that the memory window becomes larger as the fixed charge becomes smaller. This tendency is similar to that described with reference to FIG. 4A and FIG. 4B.

The addition, deletion, or design change of components, or the addition, deletion, or condition change of processes as appropriate by those skilled in the art based on the antiferroelectric memory device of an embodiment of the present invention are also included in the scope of the present invention as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

1. A nonvolatile memory device including a plurality of nonvolatile memory elements, the nonvolatile memory elements comprising:
a semiconductor layer including a metal oxide;
a gate electrode facing the semiconductor layer; and
a gate insulating layer made of an antiferroelectric material provided between the semiconductor layer and the gate electrode; wherein the electron affinity of a first material constituting the gate electrode is less than the electron affinity of a second material constituting the semiconductor layer, and
the second material is an n-type semiconductor.

2. A nonvolatile memory device including a plurality of nonvolatile memory elements, the nonvolatile memory elements comprising:
a semiconductor layer including a metal oxide;
a gate electrode facing the semiconductor layer; and
a gate insulating layer made of an antiferroelectric material provided between the semiconductor layer and the gate electrode; wherein
the electron affinity of a first material constituting the gate electrode is higher than the electron affinity of a second material constituting the semiconductor layer, and the second material is a p-type semiconductor.

3. A nonvolatile memory device including a plurality of nonvolatile memory elements, the nonvolatile memory elements comprising:
a semiconductor layer including a metal oxide;
a gate electrode facing the semiconductor layer;
a gate insulating layer made of an antiferroelectric material provided between the semiconductor layer and the gate electrode; and
an interface layer provided between the gate insulating layer and the gate electrode; wherein
the electron affinity of a first material constituting the gate electrode is less than the electron affinity of a second material constituting the semiconductor layer, the second material is an n-type semiconductor, and the interface layer is made up of a silicon oxide.

4. The nonvolatile memory device according to claim 1 or 3, wherein the gate insulating layer has a fixed charge of −2 μC/cm² to −1 μC/cm².

5. The nonvolatile memory device according to claim 1 or 3, wherein the metal oxide is a tin oxide or a composite oxide of In and Zn, and the electron affinity of the first material is 4.9 eV or less.

6. The nonvolatile memory device according to claim 5, wherein the first material is n-type doped Si and/or Ge.

7. The nonvolatile memory device according to claim 5, wherein the first material is a metallic material.

8. The nonvolatile memory device according to claim 1 or 3, wherein the metal oxide is a In oxide or a composite oxide of In, Ga, and Zn, and the electron affinity of the first material is 4.3 eV or less.

9. The nonvolatile memory device according to claim 8, wherein the first material is n-type doped Si and/or Ge.

10. The nonvolatile memory device according to claim 8, wherein the first material is a metallic material.

11. A nonvolatile memory device including a plurality of nonvolatile memory elements, the nonvolatile memory elements comprising:
a semiconductor layer including a metal oxide;
a gate electrode facing the semiconductor layer; and
a gate insulating layer made of an antiferroelectric material provided between the semiconductor layer and the gate electrode; wherein the metal oxide is a tin oxide or a composite oxide of In and Zn, and the electron affinity of a first material constituting the gate electrode is 4.9 eV or less.

12. A nonvolatile memory device including a plurality of nonvolatile memory elements, the nonvolatile memory elements comprising:
a semiconductor layer including a metal oxide;
a gate electrode facing the semiconductor layer; and
a gate insulating layer made of an antiferroelectric material provided between the semiconductor layer and the gate electrode; wherein the metal oxide is a In oxide or a composite oxide of In, Ga, and Zn, and the electron affinity of a first material constituting the gate electrode is 4.3 eV or less.

13. The nonvolatile memory device according to claim 1, 2, 3, 11 or 12, wherein the antiferroelectric material is a complex oxide expressed by HfₓZr₁₋ₓO₂ (0≤x≤0.4).

14. The nonvolatile memory device according to claim 1, 2, 3, 11 or 12, wherein the gate insulating layer has a film thickness of 5 nm or more to 50 nm or less.
